(19) United States
(12) Patent Application Publication
(10) Pub. No.: US 2026/0026082 A1
(43) Pub. Date: Jan. 22, 2026

(54) TRENCH-GATE PLANAR-GATE SEMICONDUCTOR DEVICE WITH MONOLITHICALLY INTEGRATED SCHOTTKY BARRIER DIODE AND JUNCTION SCHOTTKY BARRIER DIODE

(71) Applicant: Huawei Digital Power Technologies Co., Ltd., Shenzhen (CN)

(72) Inventors: Samir Mouhoubi, Nuremberg (DE); Tomasz Sledziewski, Munich (DE)

(73) Assignee: Huawei Digital Power Technologies Co., Ltd., Shenzhen (CN)

(21) Appl. No.: 19/322,895

(22) Filed: Sep. 9, 2025

Related U.S. Application Data
(63) Continuation of application No. PCT/EP2023/065451, filed on Jun. 9, 2023.

(30) Foreign Application Priority Data
Mar. 9, 2023 (WO) PCT/EP2023/055974
Mar. 9, 2023 (WO) PCT/EP2023/055978
Mar. 9, 2023 (WO) PCT/EP2023/055980

(51) Int. Cl. H10D 84/00; H10D 8/00; H10D 8/01; H10D 8/60; H10D 12/00; H10D 12/01; H10D 30/01; H10D 30/66; H10D 62/10; H10D 64/27

(52) U.S. Cl. CPC H10D 84/146; H10D 8/045; H10D 8/051; H10D 8/411; H10D 8/60; H10D 12/038; H10D 12/481; H10D 30/0297; H10D 30/668; H10D 62/102; H10D 62/124; H10D 64/514; H10D 64/518; H10D 84/143; H10D 84/161

(57) ABSTRACT

A trench-gate planar-gate semiconductor device with monolithically integrated Schottky barrier diode and Junction Schottky barrier diode, where the semiconductor device includes at least one semiconductor cell. The semiconductor cell includes: a substrate arranged at a bottom surface of the semiconductor cell; a vertical channel section placed above the substrate; a planar channel section formed above the substrate and below a trench that is formed on both sides of the vertical channel section; a Schottky section placed above the substrate; and a Junction Schottky section placed above the substrate. The vertical channel section and the Schottky section are placed in a mesa section of the semiconductor device along a first direction parallel to the bottom surface. The planar channel section and the Junction Schottky section are placed below the trench along the first direction parallel to the bottom surface.

### CROSS-REFERENCE TO RELATED APPLICATIONS

This application is a continuation of International Application No. PCT/EP2023/065451, filed on Jun. 9, 2023, which claims priority to International Patent Application No. PCT/EP2023/055980, filed on Mar. 9, 2023, and International Patent Application No. PCT/EP2023/055978, filed on Mar. 9, 2023, and International Patent Application No. PCT/EP2023/055974, filed on Mar. 9, 2023. All of the aforementioned patent applications are hereby incorporated by reference in their entireties.

### FIELD

The present disclosure relates to the field of power semiconductor devices, including trench-gate semiconductor devices and elementary cells of such devices and methods for their production. The present disclosure also relates to a trench-gate planar-gate semiconductor device with monolithically integrated Schottky barrier diode (SBD) and Junction Schottky barrier diode (JSBD) and a method for manufacturing such devices.

### BACKGROUND

A key silicon carbide power device is Power metal-oxide-semiconductor field-effect transistor (MOSFET), which integrates thousands of unit (elementary) cells. In order to obtain low device resistance, high cell integration in a defined device active area must be ensured, which is achieved by a shrinkage of a cell pitch. The shrinkage of the cell pitch is enabled by process and design optimization, for example by a transition from a planar-gate structure to a trench-gate structure. A challenge of the trench-gate Silicon Carbide (SiC) MOSFET can be how to shield a trench bottom and a gate oxide from high electric fields.

A further feature of the power MOSFET is presence of a pn-junction, so-called body diode, which can be used for current conduction (freewheeling) when the polarity of the drain-source voltage is reversed compared to the on-state conditions, which may happen for example in inductively switching circuits. In this particular case, the MOSFET, which in its nature is a unipolar device, enters into a bipolar conduction mode. Usage of the parasitic body diode is a preferred solution, because it enables elimination of external freewheeling diodes from a circuit, decreases the number of elements and a total application cost, which is especially important in case of costly SiC technology.

However, in case of SiC, utilization of the body diode for freewheeling might lead to serious device reliability issues. The presence of minority carriers (bipolar conduction) at concentrations above a certain threshold concentration level results in so-called bipolar degradation. Electron-hole recombination induces Shockley stacking faults (SSF) from basal plane dislocations (BPD) under forward bipolar operation. The SSF expand further with higher currents or stress and might cause degradation of threshold voltage, on-state resistance and current gain of a device.

### SUMMARY

Embodiments of the present disclosure provide a solution for a power device with improved reliability without the problems described above.

Embodiments of the present disclosure provide for a trench-gate semiconductor device with an improved trench bottom shield whose reliability is additionally improved by suppression of freewheeling current conduction through a body diode. Embodiments presented herein results in improved power density and reliability, in particular when used in wide bandgap power semiconductor devices such as SiC MOS power devices.

Embodiments of the present disclosure are applicable to any power conversion system or architecture using semiconductor power devices. Embodiments described hereinafter are applicable when high blocking voltage, high current density and high switching frequency are required. Embodiments of the present disclosure are applicable to all power electronic systems targeting energy loss, application size and total application cost reduction.

Products included in the embodiments described hereinafter of the present disclosure can be power electronics products, particularly DC and AC converters used in photovoltaics, electric vehicles, chargers and on-board chargers, data centers, railway and others.

Embodiments of the present disclosure provide how to implement the shield and how to integrate SBD into SiC trench-gate MOSFET and a JSBD into SiC planar-gate MOSFET without decreasing the device current density. An embodiment of the present disclosure presents how to monolithically integrate four devices, which are planar-gate MOSFET, trench-gate MOSFET, SBD and JSBD. The function of the integrated planar-gate MOSFET is to compensate for the shield presence by increase of the current density. The function of integrated SBD is to suppress the operation of the body diode in order to prevent from bipolar degradation. The function of the JSBD is to enhance the suppression of the operation of the body diode in order to prevent from the bipolar degradation.

Embodiments presented in the present disclosure will be exemplarily described hereinafter for the SiC MOSFET, but it may also be applicable to other materials, e.g., silicon (Si), gallium nitride (GaN), gallium oxide (Ga2O3) and others, and to other devices, e.g., insulated gate bipolar transistor (IGBT).

In order to describe the present disclosure in detail, the following terms, abbreviations and notations will be used:

| | |
|---|---|
| SBD | Schottky Barrier Diode |
| JSBD | Junction Schottky Barrier Diode |
| MOS | Metal Oxide Semiconductor |
| FET | Field Effect Transistor |
| MOSFET | Metal Oxide Semiconductor Field Effect Transistor |
| S | Source |
| D | Drain |
| G | Gate |
| SiC | Silicon Carbide |
| IGBT | Insulated Gate Bipolar Junction Transistor |
| JFET | Junction Field Effect Transistor |
| CSL | Current Spreading Layer |
| SSF | Shockley Stacking Faults |
| BPD | Basal Plane Dislocations |

As used herein Device active area includes an area which conducts a forward electric current; e.g. it is smaller than a device total area.

As used herein Device total area can be understood as a chip (die) area that consists of the active area and all peripheries, e.g. an edge termination, scribe lines (dicing streets), contact pads (e.g. a gate contact) and others.

As used herein Forward electric current includes a main electric current flowing through a device during its on-state.

As used herein Edge termination includes a region extending outside of the active area whose function is to reduce an electric field in outer part of a device.

As used herein a Source includes a region in MOSFET which injects majority carriers during the on-state.

As used herein a Drain includes a region in MOSFET which collects majority carriers during the on-state.

As used herein an Emitter includes a region in IGBT which injects majority carriers during the on-state.

As used herein a Collector includes a region in IGBT which collects majority carriers and injects minority carriers during the on-state.

As used herein Majority carriers include electric carriers (electrons or holes) which dominate in the forward electric current conduction; their density is much bigger than the density of minority carriers.

As used herein Minority carriers include electric carriers (electrons or holes) whose density is much lower than the density of the majority carriers.

As used herein a Gate includes a voltage-controlled region in MOSFET or IGBT which switches a device between the on-state and the off-state.

As used herein a Drift layer includes a region in MOSFET or IGBT which conducts the electric current in the on-state and sustains the biggest portion of an applied voltage (blocking voltage) in the off-state (blocking state).

As used herein a Channel includes a region in a body region of MOSFET or in a base region of IGBT to which the electric carriers are injected from the source or from the emitter, respectively, and whose conduction is controlled by the gate.

As used herein a Body region includes a region in MOSFET of an opposite doping type to the doping type of the source and drift layer, which contains the channel and which creates a pn-junction with the drift layer.

As used herein a Base region includes a region in IGBT of an opposite doping type to the doping type of the source and drift layer, which contains the channel and which creates a pn-junction with the drift layer.

As used herein a JFET region includes a region between the body regions or base regions or MOSFET or IGBT, respectively.

As used herein a CSL includes a region below the JFET region whose function is to spread the electric current in order to reduce an on-state resistance.

As used herein a Mesa includes a mesa or mesa region or mesa section of the semiconductor device is an area on a semiconductor wafer where the semiconductor has not been etched away. A mesa can be seen as a flat-topped mountain; on a semiconductor a mesa may also rise above the surrounding semi-insulating substrate.

In the present disclosure, power MOSFETs, Schottky Barrier Diodes (SBDs) and Junction Schottky Barrier Diodes (JSBDs) are described. The power MOSFET is a key semiconductor power device, in which an electrical current flow is forced by a voltage applied between a drain electrode and a source electrode, and which is controlled by a voltage applied between a gate electrode and the source electrode.

As described above, a feature of the power MOSFET is presence of a pn-junction, so-called body diode, which can be used for current conduction (freewheeling) when the polarity of the drain-source voltage is reversed compared to the on-state conditions, which may happen for example in inductively switching circuits. In this particular case, MOSFET, which in its nature is a unipolar device, enters into a bipolar conduction mode. Usage of the parasitic body diode enables elimination of external freewheeling diodes from a circuit and decreases a total application cost, which is especially important in case of a costly silicon carbide (SiC) technology.

Due to the bipolar degradation, the body diode of SiC MOSFET is often not recommended for use. Instead, Schottky barrier diode (SBD) can be monolithically integrated with SiC MOSFET, which is a cheaper solution than using an external SiC SBD for freewheeling. In such devices, operation suppression of the body diode can be achieved by an SBD preferential for current conduction. This is achieved by design and process optimization, particularly by increase of current density and decrease of resistance in the SBD-part of the device. Embodiments of the present disclosure provide for integrating SBD and JSBD into trench-gate MOSFET, in particular using the SiC technology.

The Schottky diode, also known as Schottky barrier diode (SBD), is a semiconductor diode formed by the junction of a semiconductor with a metal. It has a low forward voltage drop and a very fast switching action. When sufficient forward voltage is applied, current flows in the forward direction.

The Schottky barrier diode is a unipolar diode that offers extremely high switching speed, but suffers from high leakage current. A unipolar diode means that the current conduction is governed only by majority carriers (electrons). The Junction Schottky Barrier diode (JSBD) is a unipolar diode, which is assisted by a PN junction. This PN junction does not participate to the current conduction but rather contributes to reduce the electric field at the Schottky contact of the SBD (leading to leakage reduction). In this way, the reliability of the SBD is improved.

According to a first aspect, the present disclosure relates to a trench-gate planar-gate semiconductor device with monolithically integrated Schottky barrier diode and Junction Schottky barrier diode, the semiconductor device comprising at least one semiconductor cell, the at least one semiconductor cell comprising: a substrate being arranged at a bottom surface of the at least one semiconductor cell; a vertical channel section placed above the substrate, the vertical channel section comprising a current spreading layer, a body-body separation region, a mesa body region and a mesa source region; a planar channel section formed above the substrate and below a trench that is formed on both sides of the vertical channel section, the planar channel section comprising a layer stack of the current spreading layer, a trench body region and a trench source region; a Schottky section placed above the substrate, the Schottky section comprising the current spreading layer, the body-body separation region and a mesa Schottky contact region; a Junction Schottky section placed above the substrate, the Junction Schottky section comprising the current spreading layer, the trench body region and a Junction Schottky contact region, wherein the vertical channel section and the Schottky section are placed in a mesa section of the semiconductor device along a first direction parallel to the bottom surface; and wherein the planar channel section and the Junction Schottky section are placed below the trench along the first direction parallel to the bottom surface.

The semiconductor device of the present disclosure provides how to monolithically integrate four devices, which are planar-gate MOSFET, trench-gate MOSFET, SBD and JSBD. The current density is increased due to the planar channels.

The device has low resistance due to high channel integration, and at the same time the device reliability, switching speed and dynamic resistance are granted by a presence of a highly doped contact in every body region. In addition, the integrated Schottky and Junction Schottky diodes suppress the operation of the body diode and prevents from bipolar degradation.

In an exemplary implementation of the semiconductor device, the trench is formed next to the vertical channel section and next to the Schottky section and above the substrate along the first direction, the trench formed on both sides of the vertical channel section and of the Schottky section, the trench comprising a trench bottom and at least one trench side wall.

In an exemplary implementation of the semiconductor device, the trench body region forms a shield below the trench, the shield covering the trench bottom for protection against high electric fields.

Such a semiconductor device is not losing active area when incorporating a shield into trench-gate SiC MOSFET. In addition, the shield in trench-gate MOSFET acts as the body region of planar-gate MOSFET.

The active area is not lost because the shield is below the trench and self-aligned on the trench. The current density can be increased by using shield as a body, adding the source regions and creating the planar channels. Reliability is improved by embedding SBD and JSBD and not using body diode. Current density is not decreased by adding SBD, because SBD is shifted to the mesa above the JFET region. Current density is not decreased by adding JSBD, because JSBD is shifted to the shield region.

Such a semiconductor device provides a monolithical integration of trench-gate MOSFET and planar-gate MOSFET together with SBD and JSBD diodes, where the shield in trench-gate MOSFET acts as the body region of planar-gate MOSFET. For this device, despite the presence of the shield and SBD and JSBD, high current density and low on-state resistance can be achieved.

Note that trench-gate MOSFET with a shield is a baseline. The shields can be improved by adding source and creating channels. It means that the shield acts as the body of new embedded planar-gate MOSFET.

In an exemplary implementation of the semiconductor device, the semiconductor device comprises: a body contact region formed in the vertical channel section and the planar channel section along a second direction parallel to the bottom surface, the body contact region electrically connecting the trench body region of the planar channel section with the mesa body region of the vertical channel section.

In such a semiconductor device the body contact improves reliability, switching characteristics and dynamic resistance.

In an exemplary implementation of the semiconductor device, one or more planar carrier channels are formed in each planar channel section, one or more vertical carrier channels are formed on each trench side wall of the vertical channel section, and one or more Schottky barrier diodes are formed in at least one Schottky section; and one or more Junction Schottky barrier diodes are formed in each trench bottom.

In such semiconductor device, despite the presence of the shield, high current density and low on-state resistance can be achieved.

The trench body region and the mesa body region can be formed by several subregions of the same type, for example. Each of implanted regions described above can be produced by one or more than one ion implantation shot.

The second direction can be orthogonal to the first direction or can be within an angle between 0 and 90 degrees, for example.

In an exemplary implementation of the semiconductor device, the at least one semiconductor cell comprises: a buffer layer placed on top of the substrate; and a drift layer placed on top of the buffer layer; wherein the vertical channel section and the Schottky section and the Junction Schottky section are placed on top of the drift layer.

The buffer layer allows design flexibility. The buffer layer may be a first deposited layer and the drift layer a second deposited layer. The semiconductor cell is not limited to these two layers, it understands that even more layers can be deposited. For example, the drift layer can be decomposed into a plurality of layers which have different functions, or different parameters but the same function. In other words, there are basically two layers, the buffer layer and the drift layer, but the number of layers is not limited to two. There may be other layers having another function than the drift layer and the buffer layer. This provides a high degree of design flexibility when designing the semiconductor cells and the trench-gate planar-gate semiconductor device.

In an exemplary implementation of the semiconductor device, the substrate, the buffer layer, the drift layer, the current spreading layer, the trench source region, the body-body separation region, the mesa source region, the mesa Schottky contact region and the Junction Schottky contact region are of a first semiconductor doping type; and the trench body region, the mesa body region and the body contact region are of a second semiconductor doping type.

In an exemplary implementation of the semiconductor device, the Junction Schottky contact region is fully surrounded or at least partly surrounded by the trench body region. The area of the source contact region in the trench and the area of the Junction Schottky contact region in the trench allow to control the ratio of the forward current (on-state resistance) and Schottky current (reverse conduction) of the planar MOSFET.

In an exemplary implementation of the semiconductor device, the Junction Schottky contact region is surrounded by the trench body region on two sides of the Schottky contact region, the two sides extending along the second direction. This provides design flexibility.

In an exemplary implementation of the semiconductor device, a current density of the semiconductor device in which the Schottky contact region is partly surrounded by the trench body region is higher than a current density of the semiconductor device in which the Schottky contact region is fully surrounded by the trench body region. This results in design flexibility with respect to current density and strength of electric field.

In an exemplary implementation of the semiconductor device, a forward current versus Schottky current ratio of the semiconductor device is based on a ratio between an area of the mesa source region and an area of the Schottky contact region. This allows a flexible design with respect to forward current versus Schottky current ratio.

In an exemplary implementation of the semiconductor device, a forward current versus Junction Schottky current ratio of the semiconductor device is based on a ratio between an area of the trench source region and an area of the Junction Schottky contact region. This allows further flexible design with respect to forward current versus Schottky current ratio.

In an exemplary implementation of the semiconductor device, a reverse conduction of the semiconductor device is shared by the Schottky contact region and the Junction Schottky contact region which regions are weighted by their respective areas. This allows adjustment of reverse conduction by design.

In an exemplary implementation of the semiconductor device, the trench source region is implanted self-aligned through a spacer on the trench body region. This implementation allows for smaller pitch of the device and for reduction of the number of process steps. The trench source region may be directly implanted into the trench body region through a spacer mask, for example.

In an exemplary implementation of the semiconductor device, the current spreading layer is shallower than the trench body region of the planar channel section. The shallower current spreading layer allows higher blocking voltage of the device due to lower electric field at the trench body and/or in the gate oxide.

The term “shallower” means here that the current spreading layer is smaller or thinner than the trench body region in the planar channel section. That means, a thickness of the current spreading layer is less than a thickness of the layer represented by the trench body region. “Shallower” means smaller absolute value at y-axis. For example, when CSL is placed at a depth of 2 um and the shield reaches the depth of 3 um, CSL is shallower than the shield.

In an exemplary implementation of the semiconductor device, a first planar carrier channel is formed between the trench source region and the current spreading layer of a first part of each planar channel section and a second planar carrier channel is formed between the trench source region and the current spreading layer of a second part of each planar channel section; wherein a first vertical carrier channel is formed on each trench side wall between the mesa source region and the current spreading layer of a first part of the vertical channel section and a second vertical carrier channel is formed on each trench side wall between the mesa source region and the current spreading layer of a second part of the vertical channel section; wherein a Schottky contact is formed on top of the mesa Schottky contact region; wherein a first Schottky barrier diode is formed by a first part of the Schottky contact and the mesa Schottky contact region of a first part of the vertical channel section and a second Schottky barrier diode is formed by a second part of the Schottky contact and the mesa Schottky contact region of a second part of the vertical channel section; and wherein a Junction Schottky barrier diode is formed by the Junction Schottky contact region and the trench body region.

This results in a highly integrated semiconductor device where multiple carrier channels and Schottky barrier diodes can be monolithically integrated in one semiconductor cell. The Schottky contact defines a metal contact; the mesa Schottky contact region defines a semiconductor region. The Schottky barrier diodes are formed by the metal and the semiconductor.

In one exemplary implementation, the semiconductor device can be a Silicon Carbide device, for example. Such SiC device enables higher switching frequencies and provides a reduced application size, as compared to silicon. Such SiC device enables lower switching losses and/or lower conduction losses comparing to silicon devices rated at a same blocking voltage.

The body contact region may be formed as a non-separated region electrically contacting the trench body region of both parts of the planar channel section with the mesa source region of both parts of vertical channel section.

In an exemplary implementation of the semiconductor device, e.g., as described below with respect to FIG. 3a, the body contact region is separated in two parts, a first part making electrical connection to the mesa body regions of both parts of the vertical channel section and a second part making electrical contact to the trench body regions of both parts of the planar channel section. This results in design flexibility for implementing the body contact region.

In an exemplary implementation of the semiconductor device, the second part of the body contact region extends to the at least one trench side wall. This also provides design flexibility for implementing the body contact region.

In an exemplary implementation of the semiconductor device, the first part and the second part of the body contact region are arranged staggered along the first direction with respect to each other. This also provides design flexibility for implementing the body contact region.

In an exemplary implementation of the semiconductor device, the second part of the body contact region forms a stripe-shaped region extending next to and in parallel to the trench source region; and/or wherein the second part of the body contact region forms a patterned-shaped region with the trench source region. The shape of the body contacts is drawn as rectangles for exemplary purpose. It should be understood that any geometrical shape can be used: circles, ovals, hexagons, etc. This also provides design flexibility for implementing the body contact region.

In an exemplary implementation of the semiconductor device, the at least one semiconductor cell comprises: a gate electrode formed in the trench above the planar carrier channels, the gate electrode having an overlay with the trench source region; a first ohmic contact formed in the trench above the trench source region and the body contact region, the first ohmic contact providing a first part of a source contact; a first Schottky barrier diode contact formed above the mesa Schottky contact region of a first part of the Schottky section; a second Schottky barrier diode contact formed above the mesa Schottky contact region of a second part of the Schottky section; a Junction Schottky barrier diode contact formed above the Junction Schottky contact region; and a second ohmic contact formed above the mesa source region and the body contact region between the first Schottky barrier diode contact and the second Schottky barrier diode contact, the second ohmic contact providing a second part of the source contact; and an interlayer dielectric layer electrically separating the gate electrode from the first and second ohmic contacts. Such a design provides separate ohmic contacts in planar channel and vertical channel sections, and monolithically integrated Schottky barrier diodes and Junction Schottky barrier diode.

In an exemplary implementation of the semiconductor device, the interlayer dielectric layer is formed in the trench and overlays the mesa source region on top of the vertical channel section and the mesa Schottky contact region on top of the Schottky section. Such a design of the interlayer dielectric layer provides a separation of the gate electrode from the ohmic contacts in the planar channel and vertical channel sections.

In an exemplary implementation of the semiconductor device, the interlayer dielectric layer is formed in the trench without overlaying the mesa source region on top of the vertical channel section and the mesa Schottky contact region on top of the Schottky section. By such design the mesa source region on top of the vertical channel section and the mesa Schottky contact region on top of the Schottky section have a larger contact area when not being overlayed by the interlayer dielectric layer.

In an exemplary implementation of the semiconductor device, an oxide thickness between the trench source region and the gate is increased over an oxide thickness between the planar carrier channels and the gate and wherein an oxide thickness between the mesa source region and the gate is increased over an oxide thickness between the vertical carrier channels and the gate. The increased oxide thickness results in a smaller gate-source capacitance.

In an exemplary implementation of the semiconductor device, the second ohmic contact is extending onto a portion of the at least one trench side wall of the trench or the second ohmic contact and the Schottky contact are extending onto a portion of the at least one trench side wall of the trench. The mesa source region and the mesa Schottky contact region have a larger contact area.

In an exemplary implementation of the semiconductor device, the at least one semiconductor cell is forming a SBD and JSBD-integrated MOSFET structure; or a doping type of the substrate is of opposite doping type to the doping type of the drift layer, and the at least one semiconductor cell is forming a SBD-integrated IGBT structure. Accordingly, IGBT offers lower static (conduction) power losses than MOSFET. IGBT enables higher current densities than MOSFET or alternatively higher blocking voltages at the same current densities as MOSFET.

In an exemplary implementation of the semiconductor device, the first semiconductor doping type is an n-type doping and the second semiconductor doping type is a p-type doping; or the first semiconductor doping type is a p-type doping and the second semiconductor doping type is an n-type doping. This provides design flexibility, in particular for implementing complementary metal-oxide-semiconductor (CMOS) logic components.

In an exemplary implementation of the semiconductor device, the vertical channel section and the Schottky section are placed next to each other along the first direction or along the second direction; or the vertical channel section and the Schottky section are placed at a distance from each other along the first direction or along the second direction. This provides design flexibility, different design variations of the vertical channel section with respect to the Schottky section can be implemented.

According to a second aspect, the present disclosure relates to a method for producing at least one semiconductor cell of a trench-gate planar-gate semiconductor device with monolithically integrated Schottky barrier diode and Junction Schottky barrier diode, the method comprising: providing a substrate arranged at a bottom surface of the at least one semiconductor cell; forming a vertical channel section above the substrate, the vertical channel section comprising a current spreading layer, a body-body separation region, a mesa body region and a mesa source region; forming a trench on both sides of the vertical channel section; forming a planar channel section above the substrate and below the trench, the planar channel section comprising a layer stack of the current spreading layer, a trench body region and a trench source region; forming a Schottky section above the substrate, the Schottky section comprising a current spreading layer, a body-body separation region and a mesa Schottky contact region; forming a Junction Schottky section above the substrate, the Junction Schottky section comprising the current spreading layer, the trench body region and a Junction Schottky contact region; wherein the vertical channel section and the Schottky section are placed in a mesa section of the semiconductor device along a first direction parallel to the bottom surface; and wherein the planar channel section and the Junction Schottky section are placed below the trench along the first direction parallel to the bottom surface.

Such method allows producing a reliable semiconductor device because it is prevented from bipolar degradation by using SBD and JSBD. The method enables producing a semiconductor device with monolithically integration of trench-gate MOSFET and planar-gate MOSFET together with SBD diodes and JSBD diodes, where the shield in trench-gate MOSFET acts as the body region of planar-gate MOSFET. For this device, despite the presence of the shield, high current density and low on-state resistance can be achieved. Due to the self-alignment of the shield on the trench there is no loss of the active area. The method may further comprise: placing a buffer layer on top of the substrate; and placing a drift layer on top of the buffer layer.

In an exemplary implementation of the method, the method comprises: forming the trench next to the vertical channel section and next to the Schottky section and above the substrate along the first direction, the trench on both sides of the vertical channel section, the trench comprising a trench bottom and at least one trench side wall.

In an exemplary implementation of the method, the method comprises: forming a body contact region in the vertical channel section and the planar channel section along a second direction parallel to the bottom surface, the body contact region electrically connecting the trench body region of the planar channel section with the mesa body region of the vertical channel section. The body contact improves reliability, switching characteristics and dynamic resistance.

In an exemplary implementation of the method, the method comprises: forming one or more planar carrier channels in each planar channel section, forming one or more vertical carrier channels on each side wall of the vertical channel section and forming one or more Schottky barrier diodes in the Schottky section; and forming one or more Junction Schottky barrier diodes in each trench bottom. Such method allows producing a highly integrated semiconductor device, because multiple channels, e.g., vertical and planar channels, and Schottky barrier diodes and Junction Schottky barrier diodes are available in every unit cell. One way of producing body contact region can be to etch trench/re-grow semiconductor/planarize. Another solution is just to implant the body contact region, which does not require any trench etching.

In an exemplary implementation of the method, the trench source region is formed self-aligned on the trench body region by using a spacer process. Due to the self-aligned processing, the number of process steps and thus the manufacturing complexity can be reduced.

In an exemplary implementation of the method, the method comprises: forming a gate electrode in the trench above the planar carrier channels where no Junction Schottky barrier diodes are formed, the gate electrode having an overlay with the trench source region; forming a first ohmic contact in the trench above the trench source region and the body contact region, the first ohmic contact providing a first part of a source contact; forming a second ohmic contact above the mesa source region and the body contact region, the second ohmic contact providing a second part of the source contact; and forming an interlayer dielectric layer electrically separating the gate electrode from the first and second ohmic contacts. Such a method allows for separation of the gate electrode from the ohmic contacts in the planar channel and vertical channel sections.

In an exemplary implementation of the method, the gate electrode is formed self-aligned in the trench by using a spacer process; the interlayer dielectric layer is formed self-aligned by using a thermal oxidation process; and the first ohmic contact and the second ohmic contact are formed self-aligned by using a selective silicidation process. By that, the number of process steps can be reduced and the cell pitch can be also reduced. Due to self-aligned ILD, the pitch of the device can be decreased.

### BRIEF DESCRIPTION OF THE DRAWINGS

Further embodiments of the disclosure will be described with respect to the following figures, in which:

FIG. 1 shows a 3D structure of a semiconductor cell 100 of a trench-gate planar-gate semiconductor device with monolithically integrated Schottky barrier diode and Junction Schottky barrier diode according to the present disclosure;

FIG. 2a shows a 3D structure of the semiconductor cell 100 with an interlayer dielectric layer (ILD) according to a first example and a cross section AB of the semiconductor cell 100 before the Junction Schottky section 4, 5, 12 according to the present disclosure;

FIG. 2b shows a 3D structure of the same semiconductor cell 100 shown in FIG. 2a and a cross section AB of the semiconductor cell 100 through the Junction Schottky section 4, 5, 12 according to the present disclosure;

FIG. 2c shows a 3D structure of the semiconductor cell 100 with an interlayer dielectric layer (ILD) according to a second example and a cross section AB of the semiconductor cell 100 before the Junction Schottky section 4, 5, 12 according to the present disclosure;

FIG. 2d shows a 3D structure of the same semiconductor cell 100 shown in FIG. 2c and a cross section AB of the semiconductor cell 100 through the Junction Schottky section 4, 5, 12 according to the present disclosure;

FIG. 2e shows a 3D structure of the semiconductor cell 100 with an interlayer dielectric layer (ILD) according to a third example and a cross section AB of the semiconductor cell 100 before the Junction Schottky section 4, 5, 12 according to the present disclosure;

FIG. 2f shows a 3D structure of the same semiconductor cell 100 shown in FIG. 2e and a cross section AB of the semiconductor cell 100 through the Junction Schottky section 4, 5, 12 according to the present disclosure;

FIG. 3 shows a 3D structure of an embodiment of the semiconductor cell 100 according to the present disclosure;

FIG. 3a shows a 3D structure of a first embodiment of the semiconductor cell 100 according to the present disclosure;

FIG. 3b shows a 3D structure of a second embodiment of the semiconductor cell 100 according to the present disclosure;

FIG. 4 shows a 3D structure of a third embodiment of the semiconductor cell 100 according to the present disclosure;

FIG. 5a shows a 3D structure of a fourth embodiment of the semiconductor cell 100 according to the present disclosure;

FIG. 5b shows a 3D structure of a fifth embodiment of the semiconductor cell 100 according to the present disclosure;

FIG. 6a shows a 3D structure of a sixth embodiment of the semiconductor cell 100 and a cross section AB of the semiconductor cell 100 through the Junction Schottky section JSBD with illustration of the electric field according to the present disclosure; and

FIG. 6b shows a 3D structure of a seventh embodiment of the semiconductor cell 100 and a cross section AB of the semiconductor cell 100 through the Junction Schottky section JSBD with illustration of the electric field according to the present disclosure.

### DETAILED DESCRIPTION

In the following detailed description, reference is made to the accompanying drawings. It is understood that other aspects may be utilized and structural or logical changes may be made without departing from the scope of the present disclosure. The following detailed description, therefore, is not to be taken in a limiting sense, and the scope of the present disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

The semiconductor devices described herein may be implemented in various applications, e.g., in power conversion devices for automotive and industrial applications. The described semiconductor devices may be applied in integrated circuits and/or modules and power applications and may be manufactured according to various technologies. For example, the semiconductor devices may be utilized in logic integrated circuits, power modules, analog integrated circuits, mixed signal integrated circuits, optical circuits, memory circuits and/or integrated passives.

In the following Figures reference signs are either illustrated by arrows pointing to the respective parts or regions of the device or within parentheses at the respective regions of the device. This representation of reference signs has been chosen for a better illustration of the devices, in order to avoid long arrows pointing through large parts of the pictures.

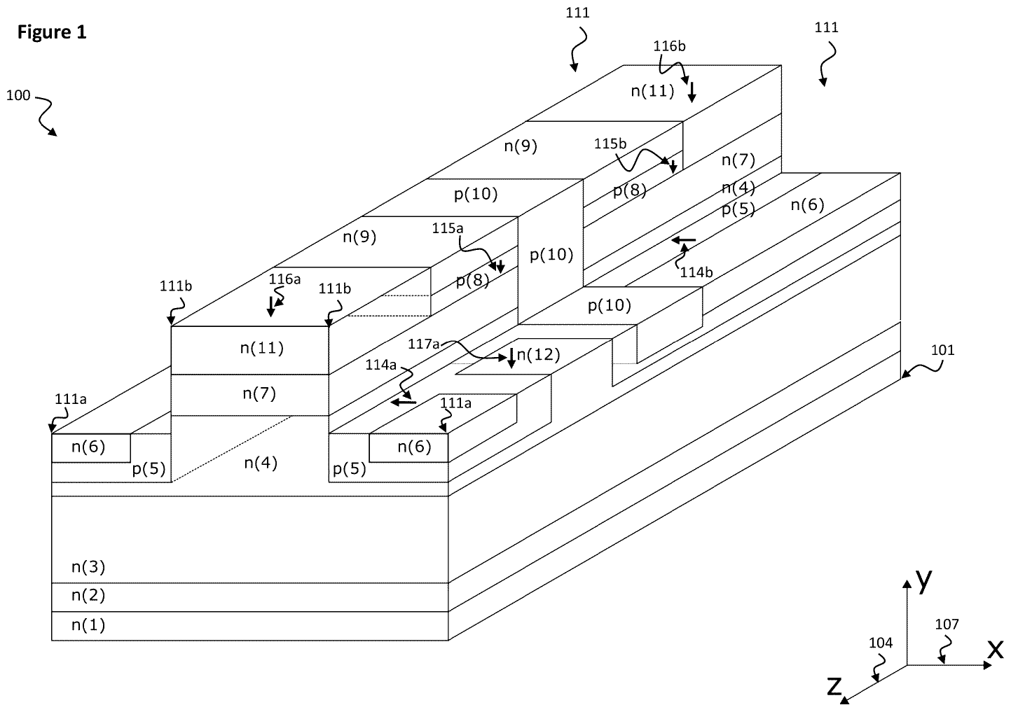

FIG. 1 shows a 3D structure of a semiconductor cell 100 of a trench-gate planar-gate semiconductor device with monolithically integrated Schottky barrier diode and Junction Schottky barrier diode according to the disclosure.

The trench-gate planar-gate semiconductor device with monolithically integrated Schottky barrier diode and Junction Schottky barrier diode comprises at least one semiconductor cell 100 as shown in FIG. 1. The semiconductor cell 100 comprises a substrate 1 being arranged at a bottom surface 101 of the at least one semiconductor cell 100.

The semiconductor cell 100 comprises a vertical channel section 4, 7, 8, 9 placed above the substrate 1. The vertical channel section 4, 7, 8, 9 comprises a current spreading layer 4, a body-body separation region 7, a mesa body region 8 and a mesa source region 9.

The semiconductor cell 100 comprises a planar channel section 4, 5, 6 formed above the substrate 1 and below a trench 111 that is formed on both sides of the vertical channel section 4, 7, 8, 9. The planar channel section 4, 5, 6 comprises a layer stack of the current spreading layer 4, a trench body region 5 and a trench source region 6.

The semiconductor cell 100 comprises a Schottky section 4, 7, 11 placed above the substrate 1. The Schottky section 4, 7, 11 comprises the current spreading layer 4, the body-body separation region 7 and a mesa Schottky contact region 11. The current spreading layer 4 and the mesa Schottky contact region 11 can be the same layers for both, the vertical channel section 4, 7, 8, 9 and the Schottky section 4, 11.

The semiconductor cell 100 comprises a Junction Schottky section 4, 5, 12 placed above the substrate 1. The Junction Schottky section 4, 5, 12 comprises the current spreading layer 4, the trench body region 5 and a Junction Schottky contact region 12.

The vertical channel section 4, 7, 8, 9 and the Schottky section 4, 7, 11 are placed in a mesa section of the semiconductor device along a first direction 104 parallel to the bottom surface 101. The planar channel section 4, 5, 6 and the Junction Schottky section 4, 5, 12 are placed below the trench 111 along the first direction 104 parallel to the bottom surface 101.

The trench 111 is formed next to the vertical channel section 4, 7, 8, 9 and next to the Schottky section 4, 7, 11 and above the substrate 1 along the first direction 104. The trench 111 may be formed on both sides of the vertical channel section 4, 7, 8, 9 and of the Schottky section 4, 7, 11. The trench 111 comprises a trench bottom 111a and at least one trench side wall 111b. Two (longer) side walls 111b may extend along the first direction 104; Other two (shorter) side walls may extend along the second direction 107.

The trench body region 5 may form a shield below the trench 111. This shield covers the trench bottom 111a for protection against high electric fields.

The semiconductor cell 100 may comprise a body contact region 10 formed in the vertical channel section 4, 7, 8, 9 and the planar channel section 4, 5, 6 along a second direction 107 (x-axis) parallel to the bottom surface 101. The body contact region 10 electrically connects the trench body region 5 of the planar channel section 4, 5, 6 with the mesa body region 8 of the vertical channel section 4, 7, 8, 9.

As can be seen from the example of FIG. 1, one or more planar carrier channels 114a, 114b are formed in each planar channel section 4, 5, 6, one or more vertical carrier channels 115a, 115b are formed on each trench side wall 111b of the vertical channel section 4, 7, 8, 9, one or more Schottky barrier diodes 116a, 116b are formed in the Schottky section 4, 7, 11, and one or more Junction Schottky barrier diodes 117a are formed in each trench bottom 111a. It understands that an arbitrary number of planar carrier channels, vertical carrier channels, Schottky barrier diodes and/or Junction Schottky barrier diodes may be formed in the respective areas.

The trench body region 5 and the mesa body region 8 can be formed by several subregions of the same type, for example. Each of implanted regions described above can be produced by one or more than one ion implantation shot.

The second direction 107 can be orthogonal to the first direction 104 (as shown in FIG. 1) or can be within an angle between 0 and 90 degrees, for example.

The semiconductor cell 100 as shown in FIG. 1 can be placed side-by-side with each other (in the second (x-axis) direction 107 and/or in the first (z-axis) direction 104) to form the semiconductor device. Depending on the illustration, the trench 111 can be formed at the sides (left side and right side in FIG. 1) of each semiconductor cell 100 as shown in FIG. 1 or the trench 111 can be formed in the middle section (middle of the left side and right side in FIG. 1) of each semiconductor cell 100.

The semiconductor cell 100 may comprise a buffer layer 2 placed on top of the substrate 1; and a drift layer 3 placed on top of the buffer layer 2. The vertical channel section 4, 7, 8, 9, the Schottky section 4, 7, 11 and the Junction Schottky section 4, 5, 12 can be placed on top of the drift layer 3 as shown in FIG. 1.

The substrate 1, the buffer layer 2, the drift layer 3, the current spreading layer 4, the trench source region 6, the body-body separation region 7, the mesa source region 9, the mesa Schottky contact region 11 and the Junction Schottky contact region 12 can be of a first semiconductor doping type, e.g., an n-doping type as shown in FIG. 1. The trench body region 5, the mesa body region 8 and the body contact region 10 can be of a second semiconductor doping type, e.g., a p-doping type as shown in FIG. 1.

Note that for clarity, in FIG. 1 and in all other Figures the reference signs of the respective layers are put in parentheses after the first or second semiconductor doping type.

The trench source region 6 can be implanted into the trench body region 5 as shown in FIG. 1. The trench source region 6 may be directly implanted into the trench body region 5 through a spacer mask, for example.

As shown in FIG. 1, the current spreading layer 4 may be deeper than the trench body region 5 in the planar channel section 4, 5, 6.

The term “deeper” means here that the current spreading layer 4 is larger or thicker than the trench body region 5 in the planar channel section 4, 5, 6. That means, a thickness of the current spreading layer 4 is greater than a thickness of the layer represented by the trench body region 5, as can be seen from FIG. 1.

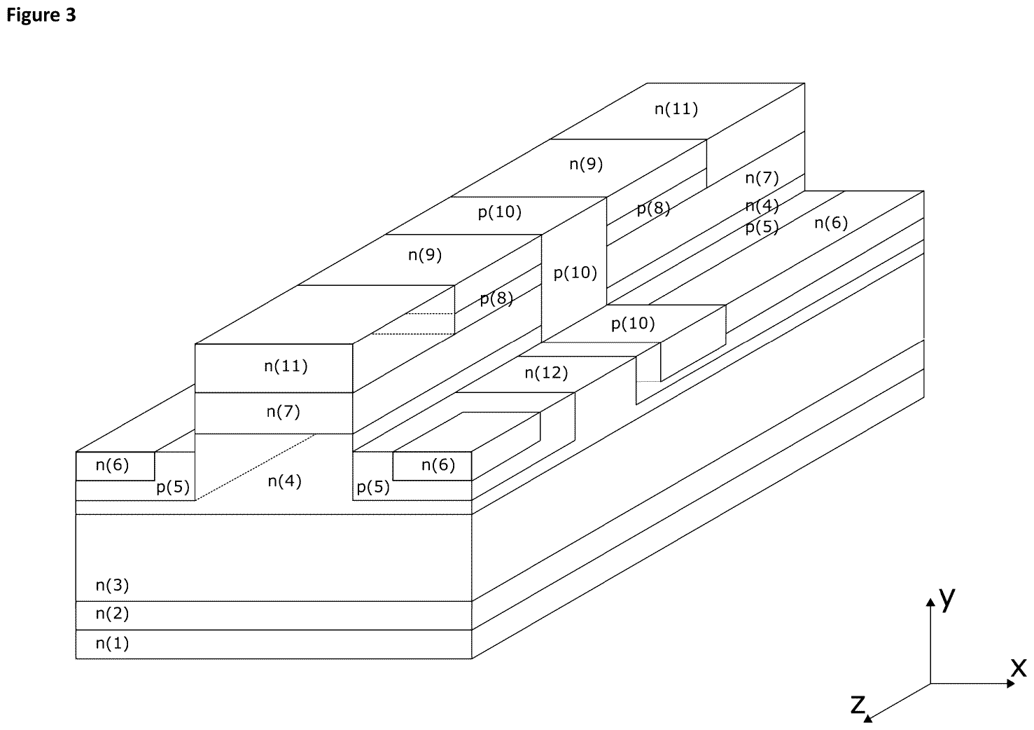

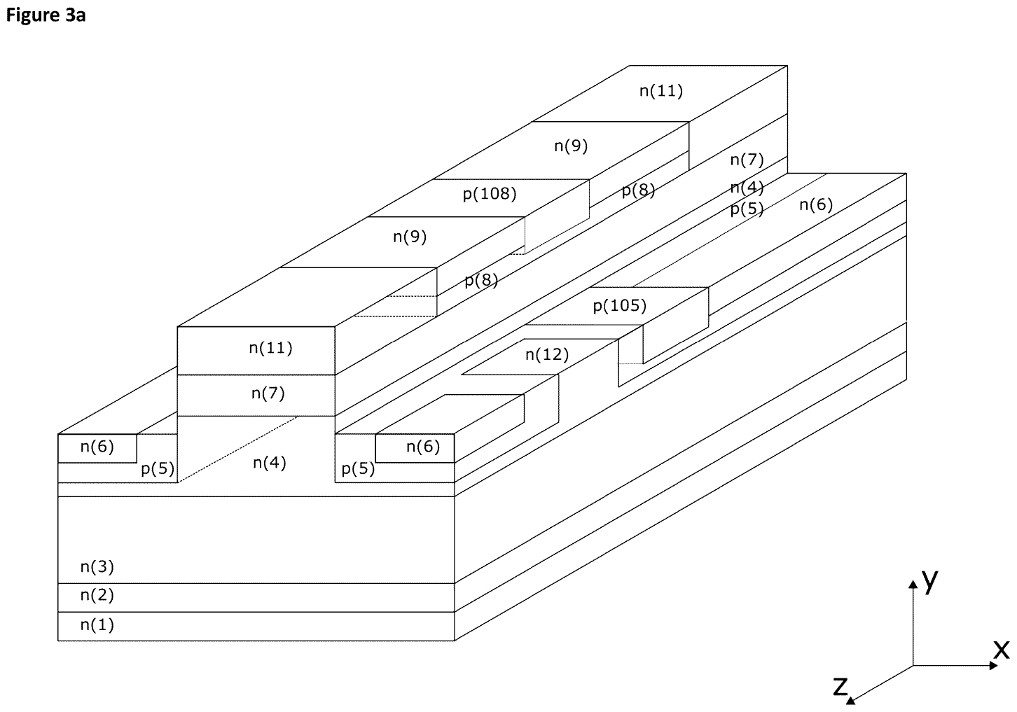

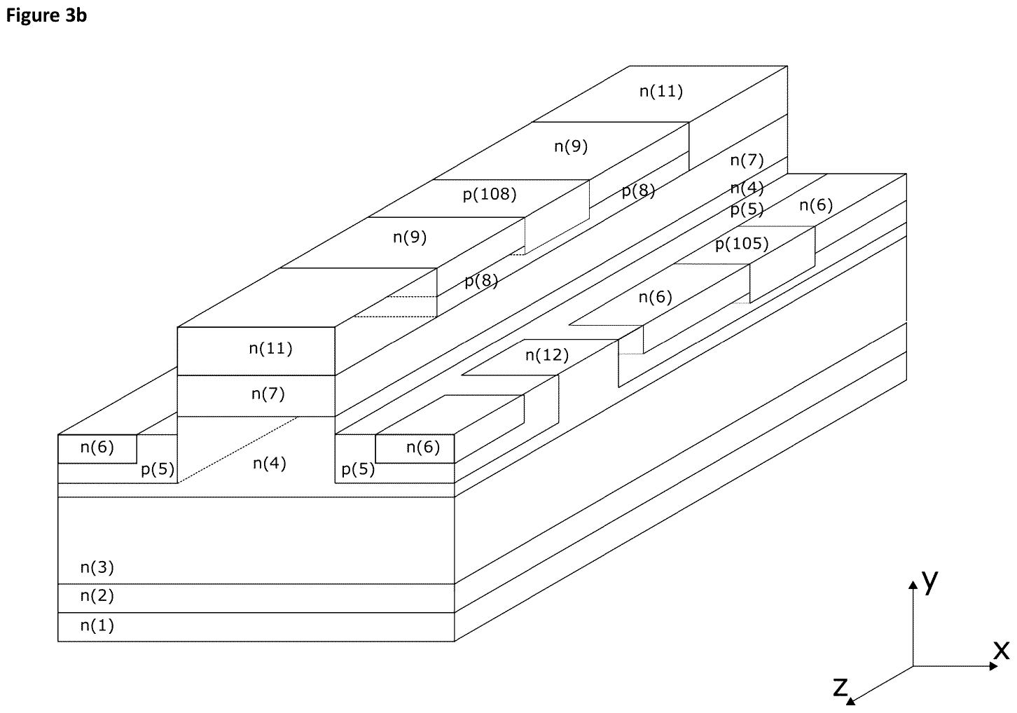

The Junction Schottky contact region 12 can be fully surrounded by the trench body region 5 as shown in FIG. 1. Alternatively, the Junction Schottky contact region 12 can be at least partly surrounded by the trench body region 5 as shown in FIG. 3, for example.

In FIG. 1, the Junction Schottky contact region 12 is surrounded by the trench body region 5 on four sides of the Schottky contact region 12. Two sides are extending along the second direction 107 and two sides are extending along the first direction 104 as shown in FIG. 1.

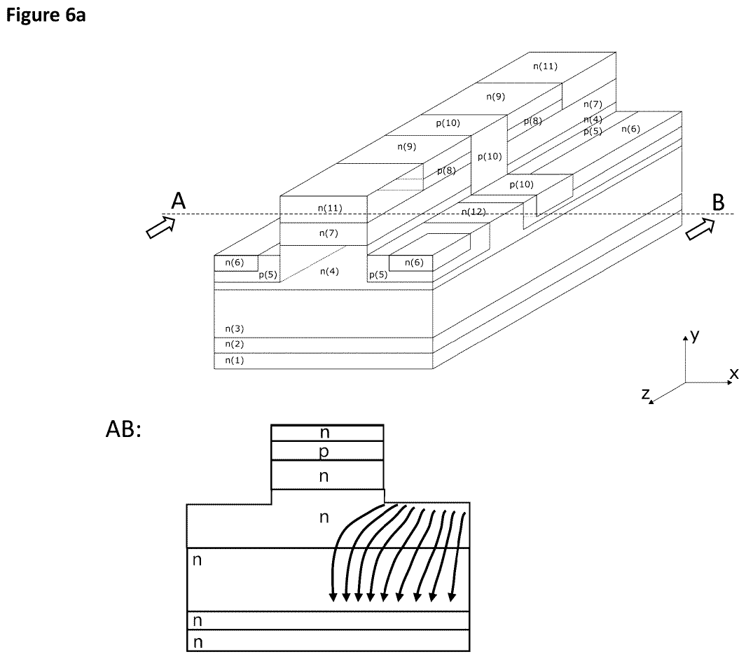

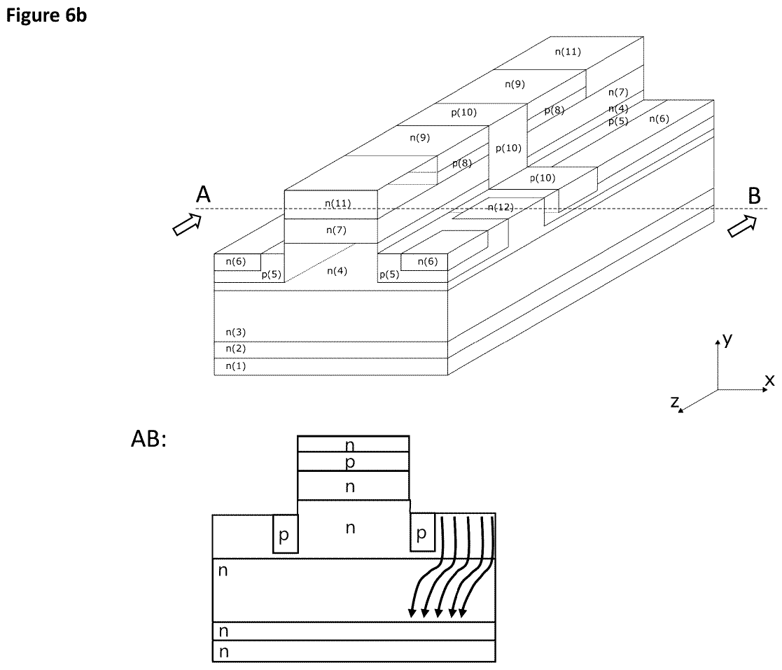

A current density of the semiconductor device in which the Junction Schottky contact region 12 is partly surrounded by the trench body region 5 is higher than a current density of the semiconductor device in which the Junction Schottky contact region 12 is fully surrounded by the trench body region 5, e.g., as shown below with respect to FIGS. 6a and 6b.

A forward current versus Schottky current ratio of the semiconductor device may be based on a ratio between an area of the mesa source region 9 and an area of the Schottky contact region 11.

A forward current versus Junction Schottky current ratio of the semiconductor device may be based on a ratio between an area of the trench source region 6 and an area of the Junction Schottky contact region 12.

A reverse conduction of the semiconductor device may be shared by the Schottky contact region 11 and the Junction Schottky contact region 12 which regions 11, 12 are weighted by their respective areas.

The trench source region 6 may be implanted self-aligned through a spacer on the trench body region 5.

A first planar carrier channel 114a can be formed between the trench source region 6 and the current spreading layer 4 of a first part of each planar channel section 4, 5, 6 as shown in FIG. 1. A second planar carrier channel 114b can be formed between the trench source region 6 and the current spreading layer 4 of a second part of each planar channel section 4, 5, 6, as shown in FIG. 1.

A first vertical carrier channel 115a can be formed on each trench side wall 111b between the mesa source region 9 and the current spreading layer 4 of a first part of the vertical channel section 4, 7, 8, 9. A second vertical carrier channel 115b can be formed on each trench side wall 111b between the mesa source region 9 and the current spreading layer 4 of a second part of the vertical channel section 4, 7, 8, 9.

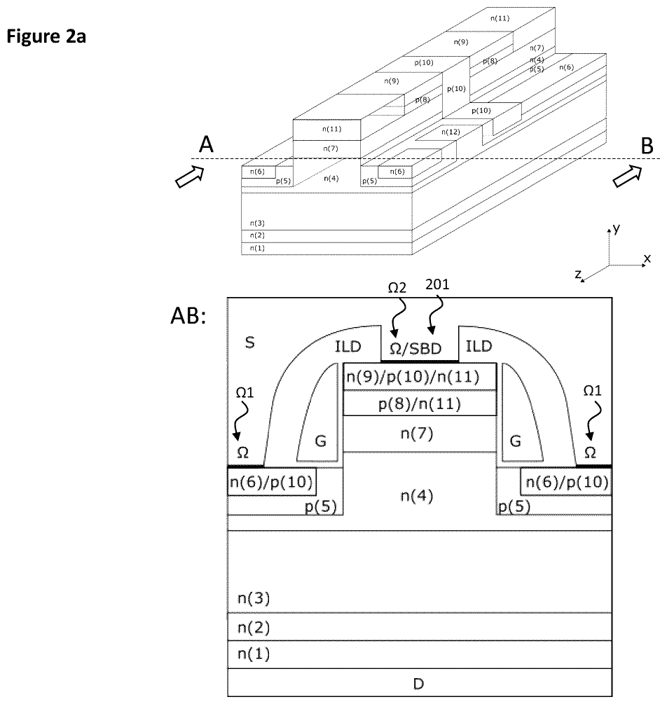

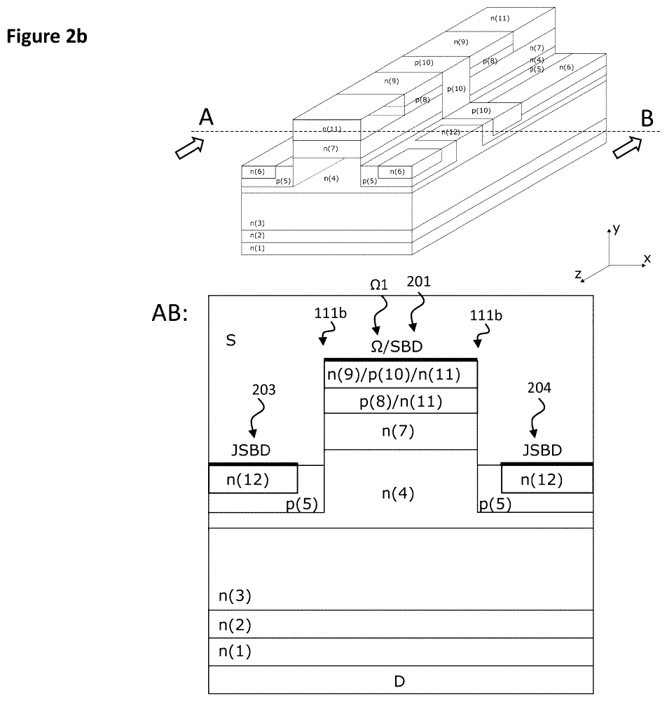

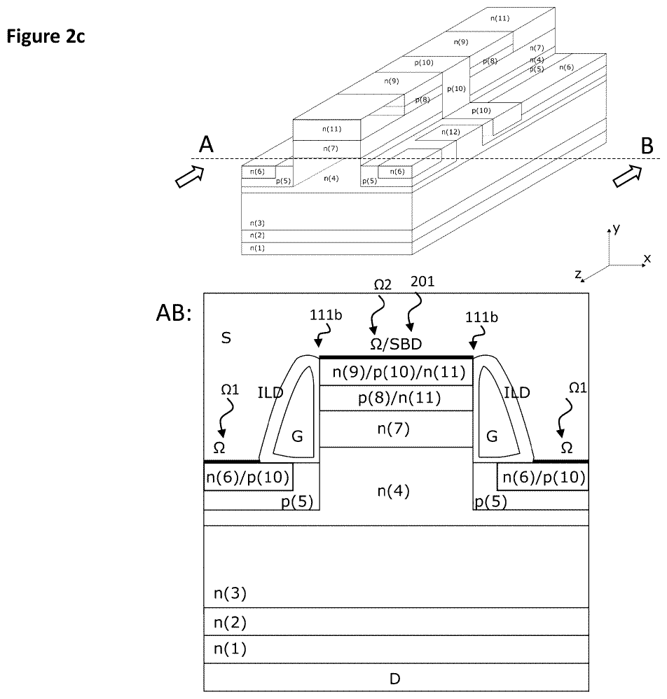

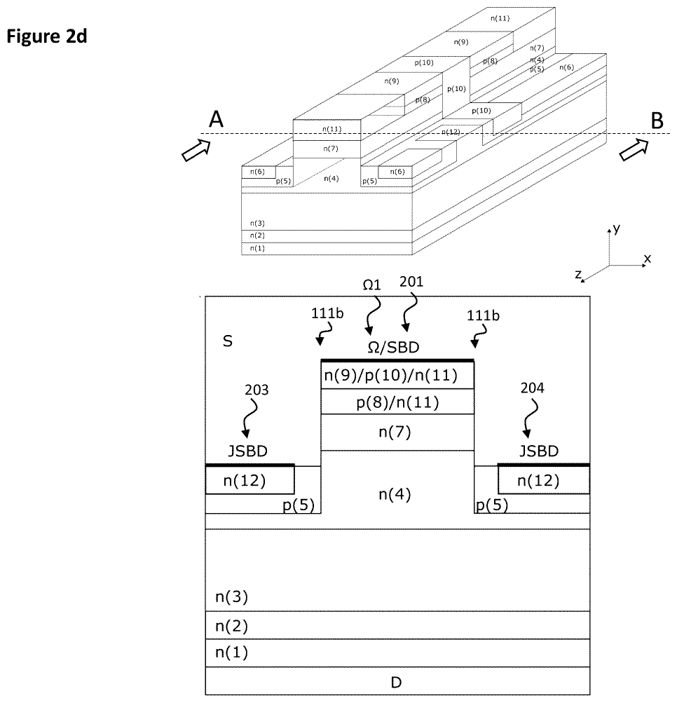

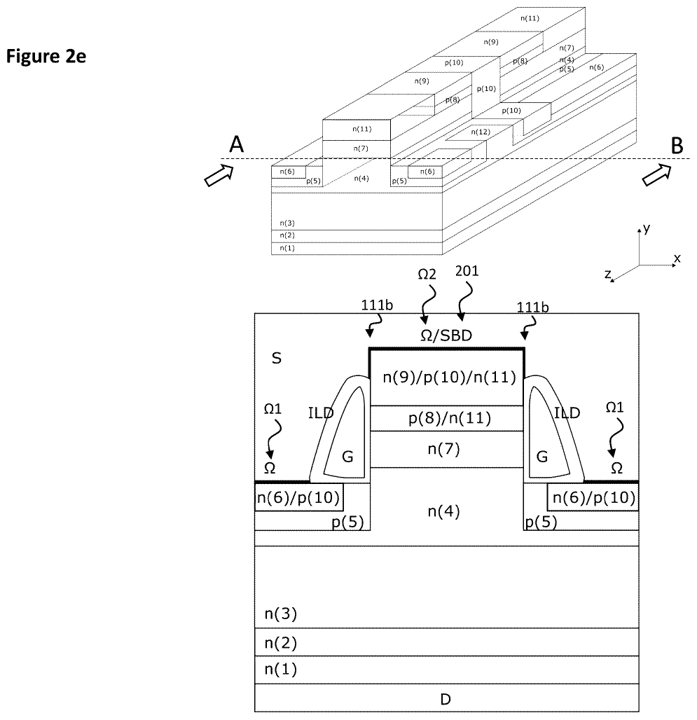

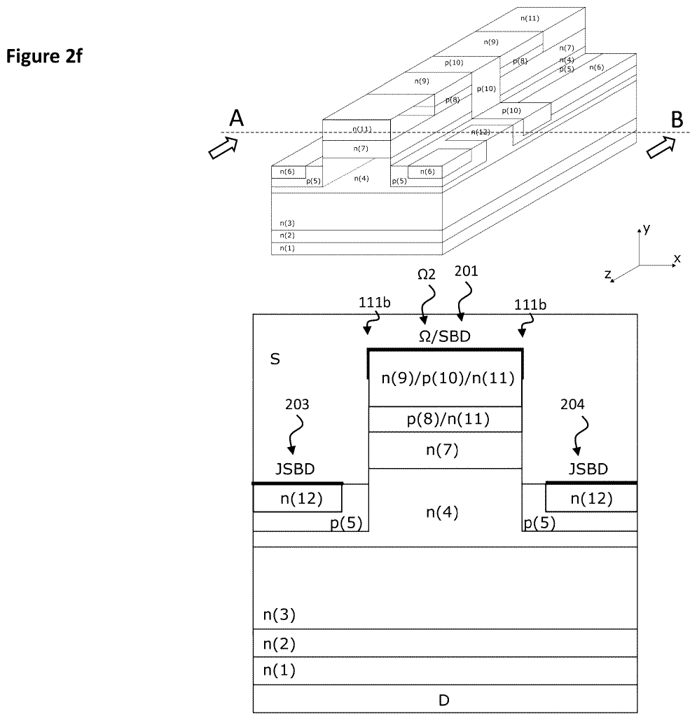

Schottky contacts 201 can be formed on top of the mesa Schottky contact region 11 as shown in FIGS. 2a to 2f.

A first Schottky barrier diode 116a can be formed by a first part of the Schottky contact 201 and the mesa Schottky contact region 11 of a first part of the vertical channel section 4, 7, 8,9. A second Schottky barrier diode 116b can be formed by a second part of the Schottky contact 201 and the mesa Schottky contact region 11 of a second part of the vertical channel section 4, 7,8, 9.

One or more Junction Schottky barrier diodes 117a can be formed in the trench bottom 111a.

The Schottky contacts 201 define metal contacts. The mesa Schottky contact region 11 defines a semiconductor region. The Schottky barrier diodes are formed by the metal and the semiconductor.

The Junction Schottky contacts 203, 204 define metal contacts. The Junction Schottky contact region 12 defines a semiconductor region. The Junction Schottky barrier diode is formed by the metal and the semiconductor.

In one exemplary implementation, the semiconductor device can be a Silicon Carbide device, for example.

The body contact region 10 may be formed as a non-separated region electrically contacting the trench body region 5 of both parts of the planar channel section 4, 5, 6 with the mesa source region 9 of both parts of vertical channel section 4, 7, 8, 9.

The semiconductor cell 100 may form an SBD and JSBD-integrated MOSFET structure. Alternatively, the semiconductor cell 100 may form an SBD and JSBD-integrated IGBT structure. For the SBD and JSBD-integrated IGBT structure, the doping of the substrate is opposite to the doping of the drift layer. For IGBT the substrate doping is opposite to the substrate doping of MOSFET.

In one example, the first semiconductor doping type can be of an n-type doping and the second semiconductor doping type can be of a p-type doping. In an alternative example, the first semiconductor doping type can be of a p-type doping and the second semiconductor doping type can be of an n-type doping.

The vertical channel section 4, 7, 8, 9 and the Schottky section 4, 7, 11 can be placed next to each other along the first direction 104 or alternatively along the second direction 107. Alternatively, the vertical channel section 4, 7, 8, 9 and the Schottky section 4, 7, 11 can be placed at a distance from each other along the first direction 104 or alternatively along the second direction 107.

As described above, the trench body region 5 has an additional function of a shield, which protects the trench bottom and corners.

In the exemplary implementation of the semiconductor cell shown in FIG. 1, the body contact region 10 is oriented under an angle to the unit cell direction (z direction), this angle is different than zero e.g. (but not limited to) under 90°, and it connects the trench body region 5 with the mesa body region 8.

The unit cell 100 or semiconductor cell, respectively, contains one or more planar 114a, 114b and one or more vertical 115a, 115b carrier channels, for example. The planar channels 114a, 114b extend in the trench body regions 5 near the trench bottom between the trench source regions 6 and the CSL 4. The vertical channels 115a, 115b extend on the trench sidewalls in the mesa body region 8 between the mesa source region 9 and the body-body separation region 7.

In addition, the unit cell 100 contains the Schottky contact regions 11. The ratio between the device forward current (on-state resistance) and the Schottky current (ability to suppress the body diode operation) can be decided by the ratio between the mesa source region 9 area and the Schottky contact region 11 area.

The unit cell 100 further contains the Junction Schottky contact regions 12. The ratio between the device forward current (on-state resistance) and the Junction Schottky current (ability to suppress the body diode operation) can be decided by the ratio between the trench source region 6 area and the Junction Schottky contact region 12 area.

The suppression of the body diode operation can be shared by the Schottky contact regions and the Junction Schottky contact regions (the contribution of each of them will be proportional to its area).

The semiconductor cell 100 shown in FIG. 1 may be produced by a method comprising the following process steps:
providing a substrate 1 arranged at a bottom surface 101 of the at least one semiconductor cell 100;
forming a vertical channel section 4, 7, 8, 9 above the substrate 1, the vertical channel section 4, 7, 8, 9 comprising a current spreading layer 4, a body-body separation region 7, a mesa body region 8 and a mesa source region 9 as shown in FIG. 1;
forming a trench 111 on both sides of the vertical channel section 4, 7, 8, 9;
forming a planar channel section 4, 5, 6 above the substrate 1 and below the trench 111, the planar channel section 4, 5, 6 comprising a layer stack of the current spreading layer 4, a trench body region 5 and a trench source region 6;
forming a Schottky section 4, 7, 11 above the substrate 1, the Schottky section 4, 7, 11 comprising a current spreading layer 4, a body-body separation region 7 and a mesa Schottky contact region 11; wherein the vertical channel section 4, 7, 8, 9 and the Schottky section 4, 7, 11 are placed in a mesa section of the semiconductor device along a first direction 104 parallel to the bottom surface 101;
forming a Junction Schottky section 4, 5, 12 above the substrate 1, the Junction Schottky section 4, 5, 12 comprising the current spreading layer 4, the trench body region 5 and a Junction Schottky contact region 12; wherein the planar channel section 4, 5, 6 and the Junction Schottky section 4, 5, 12 are placed below the trench 111 along the first direction 104 parallel to the bottom surface 101.

The method may further comprise: placing a buffer layer 2 on top of the substrate 1; and placing a drift layer 3 on top of the buffer layer 2.

The method may further comprise: forming the trench 111 next to the vertical channel section 4, 7, 8, 9 and next to the Schottky section 4, 7, 11 and above the substrate 1 along the first direction 104, the trench 111 on both sides of the vertical channel section 4, 7, 8, 9, the trench 111 comprising a trench bottom 111a and at least one trench side wall 111b.

The method may further comprise: forming a body contact region 10 in the vertical channel section 4, 7, 8, 9 and the planar channel section 4, 5, 6 along a second direction 107 parallel to the bottom surface 101, the body contact region 10 electrically connecting the trench body region 5 of the planar channel section 4, 5, 6 with the mesa body region 8 of the vertical channel section 4, 7, 8, 9.

The method may further comprise: forming one or more planar carrier channels 114a, 114b in each planar channel section 4, 5, 6; forming one or more vertical carrier channels 115a, 115b on each side wall of the vertical channel section 4, 7, 8, 9; forming one or more Schottky barrier diodes 116a, 116b in the Schottky section 4, 7, 11; and forming one or more Junction Schottky barrier diodes 117a in each or at least one trench bottom.

One way of producing body contact region 10 can be to etch trench/re-grow semiconductor/planarize. Another solution is just to implant region 10, which does not require any trench etching.

The trench source region 6 may be formed self-aligned on the trench body region 5 by using a spacer process, for example.

The method may further comprise: forming a gate electrode G in the trench 111 above the planar carrier channels 114a, 114b where no Junction Schottky barrier diodes 117a are formed, the gate electrode G having an overlay with the trench source region 6.

The method may further comprise: forming a first ohmic contact Ω1 (see FIGS. 2a to 2f) in the trench 111 above the trench source region 6 and the body contact region 10, the first ohmic contact (Ω21) providing a first part of a source contact.

The method may further comprise: forming a second ohmic contact Ω2 (see FIGS. 2a to 2f) above the mesa source region 9 and the body contact region 10, the second ohmic contact Ω2 providing a second part of the source contact.

The method may further comprise: forming an interlayer dielectric layer ILD electrically separating the gate electrode G from the first and second ohmic contacts Ω1, Ω2.

The gate electrode G may be formed self-aligned in the trench 111 by using a spacer process, for example.

The interlayer dielectric layer ILD may be formed self-aligned by using a thermal oxidation process, for example.

The first ohmic contact Ω1 and the second ohmic contact Ω2 may be formed self-aligned by using a selective silicidation process.

FIG. 2a shows a 3D structure of the semiconductor cell 100 with an interlayer dielectric layer (ILD) according to a first example and a cross section AB of the semiconductor cell 100 before the Junction Schottky section 4, 5, 12. FIG. 2b shows a 3D structure of the same semiconductor cell 100 shown in FIG. 2a and a cross section AB of the semiconductor cell 100 through the Junction Schottky section 4, 5, 12.

The semiconductor cell 100 may correspond to the semiconductor cell 100 described above with respect to FIG. 1. In contrast to FIG. 1, FIG. 2a additionally illustrates the interlayer dielectric ILD and the ohmic contacts Ω1, Ω2 and the Schottky contacts 201 of the semiconductor cell 100. The ILD layer ILD may be formed by deposition and overlays the mesa. FIG. 2b additionally illustrates the ohmic contact Ω1, the Schottky contact 201 and the Junction Schottky contacts 203, 204 of the semiconductor cell 100.

As can be seen from FIG. 2a, the semiconductor cell 100 comprises a gate electrode G formed in the trench 111 (see FIG. 1) above the planar carrier channels 114a, 114b (see FIG. 1). The gate electrode G has an overlay with the trench source region 6.

The semiconductor cell 100 comprises a first ohmic contact Ω1 formed in the trench 111 above the trench source region 6 and the body contact region 10. The first ohmic contact Ω1 provides a first part of a source contact.

The semiconductor cell 100 comprises a first Schottky barrier diode contact 201 formed above the mesa Schottky contact region 11 of a first part of the Schottky section 4, 7, 11.

The semiconductor cell 100 comprises a second Schottky barrier diode contact 201 formed above the mesa Schottky contact region 11 of a second part of the Schottky section 4, 7, 11.

The semiconductor cell 100 comprises a second ohmic contact Ω2 formed above the mesa source region 9 and the body contact region 10 between the first Schottky barrier diode contact and the second Schottky barrier diode contact. The second ohmic contact Ω2 provides a second part of the source contact.

The semiconductor cell 100 comprises an interlayer dielectric layer ILD electrically separating the gate electrode G from the first and second ohmic contacts Ω1, Ω2.

The interlayer dielectric layer ILD is formed in the trench 111 and overlays the mesa source region 9 on top of the vertical channel section 4, 7, 8, 9 and the mesa Schottky contact region 11 on top of the Schottky section 4, 7, 11.

FIG. 2b shows the cross-section AB through the Junction Schottky section 4, 5, 12. JSBD contacts 203, 204 are placed on the Junction Schottky contact regions 12 to form the JSBDs.

The sidewalls 111b of the trench 111 can be uncovered as shown in FIG. 2b. Alternatively, the sidewalls 111b can be covered by a dielectric such as the gate dielectric or an ILD. But the gate electrode G is not formed where the JSBD is present.

FIG. 2c shows a 3D structure of the semiconductor cell 100 with an interlayer dielectric layer (ILD) according to a second example and a cross section AB of the semiconductor cell 100 before the Junction Schottky section 4, 5, 12. FIG. 2d shows a 3D structure of the same semiconductor cell 100 shown in FIG. 2c and a cross section AB of the semiconductor cell 100 through the Junction Schottky section 4, 5, 12.

The semiconductor cell 100 may correspond to the semiconductor cell 100 described above with respect to FIGS. 2a and 2b. The interlayer dielectric ILD and the ohmic contacts Ω1, Ω2 and the Schottky contacts 201 of the semiconductor cell 100 are illustrated. In contrast to FIG. 2a, the interlayer dielectric ILD has a different shape. The ILD layer may be formed by thermal oxidation of the polysilicon gate and has no overlay with the mesa. The oxide thickness above the source regions is increased compared to the oxide thickness over the channel regions.

As can be seen from FIG. 2c, the interlayer dielectric layer ILD may be formed in the trench 111 without overlaying the mesa source region 9 on top of the vertical channel section 4, 7,8, 9 and the mesa Schottky contact region 11 on top of the Schottky section 4, 7, 11.

FIG. 2d shows the cross-section AB through the Junction Schottky section 4, 5, 12. JSBD contacts 203, 204 are placed on the Junction Schottky contact regions 12 to form the JSBDs.

The sidewalls 111b of the trench 111 can be uncovered as shown in FIG. 2d. Alternatively, the sidewalls 111b can be covered by a dielectric such as the gate dielectric or an ILD. But the gate electrode G is not formed where the JSBD is present.

FIG. 2e shows a 3D structure of the semiconductor cell 100 with an interlayer dielectric layer (ILD) according to a third example and a cross section AB of the semiconductor cell 100 before the Junction Schottky section 4, 5, 12. FIG. 2f shows a 3D structure of the same semiconductor cell 100 shown in FIG. 2e and a cross section AB of the semiconductor cell 100 through the Junction Schottky section 4, 5, 12.

The semiconductor cell 100 may correspond to the semiconductor cell 100 described above with respect to FIGS. 2a and 2b. The interlayer dielectric ILD and the ohmic contacts Ω1, Ω2 and the Schottky contacts 201 of the semiconductor cell 100 are illustrated. In contrast to FIGS. 2a and 2b, the interlayer dielectric ILD has a different shape. The ILD layer may be formed by thermal oxidation of the polysilicon gate with reduced thickness and has no overlay with the mesa. The oxide thickness above the source regions is increased compared to the oxide thickness over the channel regions. The sidewall of the mesa source region 9 is exposed to the metal. The depth of the mesa source region is increased compared to the previous embodiments shown in FIGS. 2a to 2d.

The second ohmic contact Ω2 may extend onto a portion of the at least one trench side wall 111b of the trench 111; or the second ohmic contact Ω2 and the Schottky contact 201 may extend onto a portion of the at least one trench side wall 111b of the trench 111.

FIG. 2f shows the cross-section AB through the Junction Schottky section 4, 5, 12. JSBD contacts 203, 204 are placed on the Junction Schottky contact regions 12 to form the JSBDs.

The sidewalls 111b of the trench 111 can be uncovered as shown in FIG. 2d. Alternatively, the sidewalls 111b can be covered by a dielectric such as the gate dielectric or an ILD. But the gate electrode G is not formed where the JSBD is present.

FIG. 3 shows a 3D structure of an embodiment of the semiconductor cell 100.

The semiconductor cell 100 corresponds to the semiconductor cell 100 described above with respect to FIG. 1, but the Junction Schottky contact region 12 is not fully surrounded by the trench body region 5, as can be seen from the Figure. As can be seen from FIG. 3, the Junction Schottky contact region 12 separates the trench body region 5 at the trench bottom into two parts.

FIG. 3a shows a 3D structure of a first embodiment of the semiconductor cell 100.

The semiconductor cell shown in FIG. 3a may correspond to the semiconductor cell 100 described above with respect to FIG. 1. In the first embodiment shown in FIG. 3a, the semiconductor cell 100 can form a trench-planar SiC MOSFET with embedded Schottky barrier diode and Junction Schottky barrier diode.

The device shown in FIG. 3a inherits most properties of the device shown in FIG. 1, but the body contact region is separated into two parts 105 and 108 which make electrical connections to the trench body region 5 and to the mesa body region 8, respectively. The body contact regions 105 and 108 do not have to be placed in-line and can be shifted in respect to each other.

In FIG. 3a, in contrast to previous FIGS. 2a to 2f, only the semiconductor part of the device is shown. The device may consist of a substrate of a first semiconductor doping type 1, a buffer layer of a first semiconductor doping type 2, a drift layer of a first semiconductor doping type 3 and a current spreading layer (CSL) of a first semiconductor doping type 4. Furthermore, the device is composed of a trench body region of a second semiconductor doping type 5, a trench source region of a first semiconductor doping type 6, a body-body separation region of a first semiconductor doping type 7, a mesa body region of a second semiconductor doping type 8, a mesa source region of a first semiconductor doping type 9, a body contact region of a second semiconductor doping type 10, a Schottky contact region 11 of a first semiconductor doping type a Junction Schottky contact region 12 of a first semiconductor doping type.

The trench body region 5 has an additional function of a shield, which protects the trench bottom and corners. The body contact region 10 is arranged at an angle to the unit cell direction (z-direction, 104). This angle can be between 0 degrees and 90 degrees, for example. The body contact region 10 connects the trench body region 5 with the mesa body region 8. The unit cell may contain one or more planar 114a, 114b (see FIG. 1) and one or more vertical 115a, 115b (see FIG. 1) carrier channels. The planar channels 114a, 114b extend in the trench body regions 5 near the trench bottom 111a between the trench source regions 6 and the CSL 4 (see FIG. 1). The vertical channels 115a, 115b extend on the trench sidewalls 111b in the mesa body region 8 between the mesa source region 9 and the body-body separation region 7. In addition, the unit cell contains the mesa Schottky contact regions 11 and the Junction contact regions 12.

The ratio between the device forward current (on-state resistance) and the Junction Schottky current (ability to suppress the body diode operation) can be decided by the ratio between the mesa source region 6 area and the Junction Schottky contact region 12 area.

The suppression of the body diode operation can be shared by the Schottky contact regions and the Junction Schottky contact regions, the contribution of each of them will be proportional to its area.

FIG. 3b shows a 3D structure of a second embodiment of the semiconductor cell 100.

The device shown in FIG. 3b inherits most properties of the device shown in FIG. 1, but the body contact region is separated into two parts 105 and 108 which make electrical connections to the trench body region 5 and to the mesa body region 8, respectively. In contrast to the device shown in FIG. 3a where the body contact regions 105 and 108 are placed in-line, in the device shown in FIG. 3b, the body contact regions 105 and 108 are shifted in respect to each other.

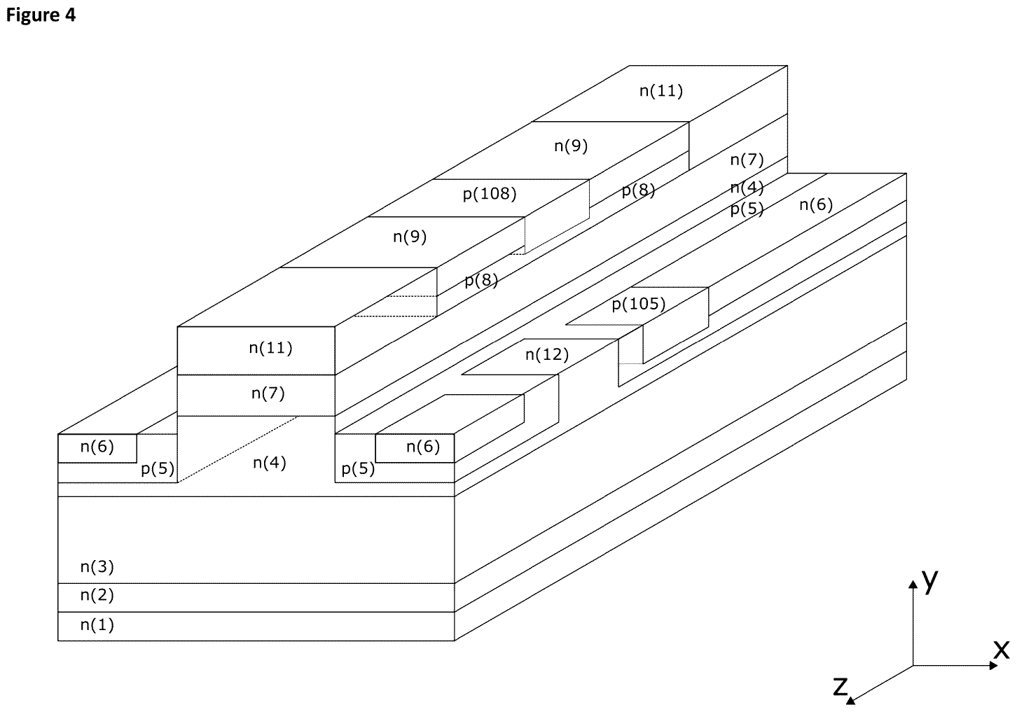

FIG. 4 shows a 3D structure of a third embodiment of the semiconductor cell 100.

The device shown in FIG. 4 inherits most properties of the device shown in FIG. 1, but the body contact region is separated into two parts 105 and 108 which make electrical connections to the trench body region 5 and to the mesa body region 8, respectively. In contrast to the device shown in FIG. 3a where the body contact region 105 extends to the trench side wall 111b, in the device shown in FIG. 4, the body contact region 105 is not extending up to the trench side wall 111b and the body contact region 105 is separated by the trench body region 5 from the trench side wall 111b.

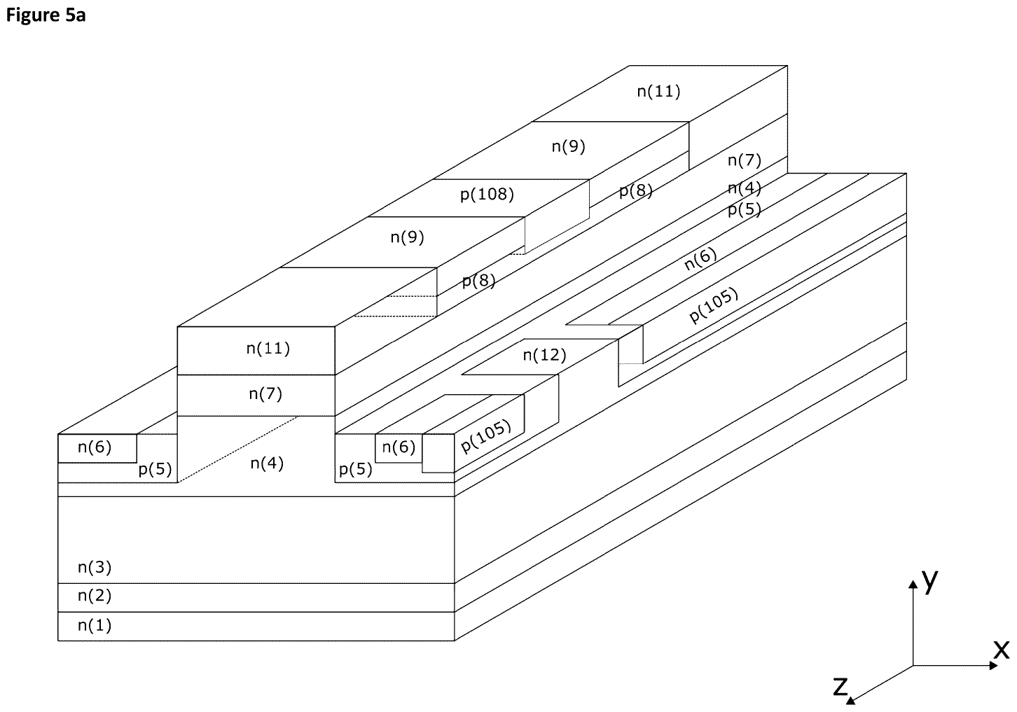

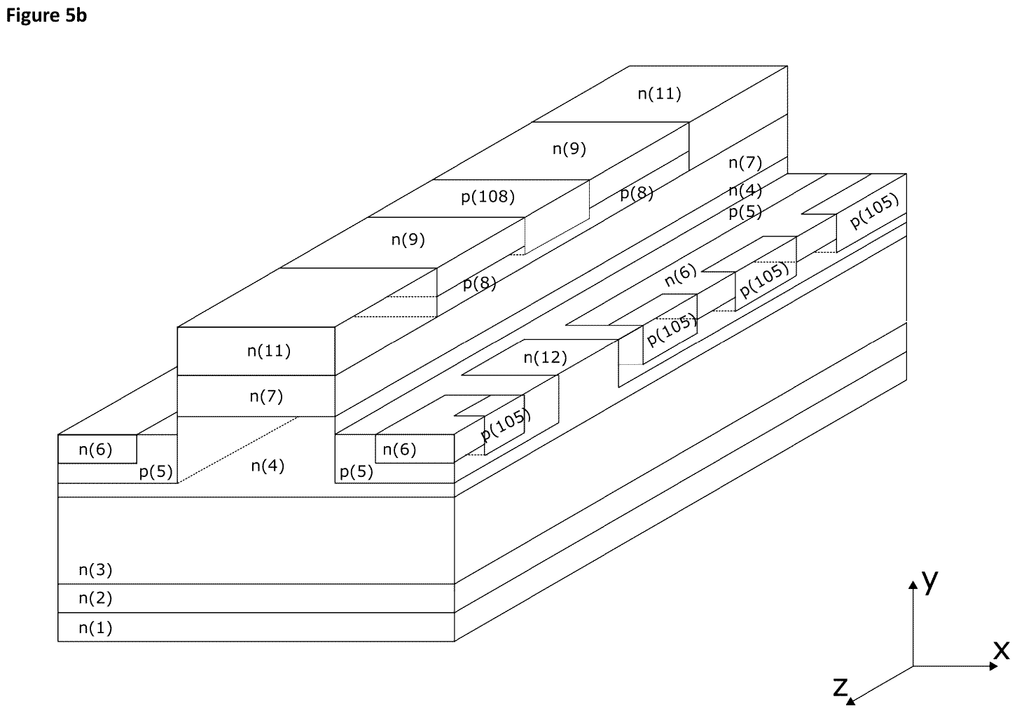

FIG. 5a shows a 3D structure of a fourth embodiment of the semiconductor cell 100.

The device shown in FIG. 5a inherits most properties of the device shown in FIG. 1, but the body contact region is separated into two parts 105 and 108 which make electrical connections to the trench body region 5 and to the mesa body region 8, respectively.

The body contact region 105 has a stripe shape and extends next to and in parallel to the trench source region 6.

The device can be fabricated according to the following exemplary process flow:

The buffer layer 2 is deposited on top of the substrate 1, the drift layer 3 is deposited on top of the buffer layer 2 and the current spreading layer 4 (optional) is formed on top of the drift layer 3.

The mesa Schottky contact region 11 (optional) is deposited on top of the CSL 4.

The body-body separation region 7 is implanted into the whole unit cell.

The mesa body region 8 is selectively implanted in entire length of the unit cell.

The stripe-shaped body contact region 10 is implanted in entire length of the unit cell; alternatively, the region can be fabricated by a combination of trench etching, epitaxial regrowth and planarization.

A mask M1 is deposited on top of the semiconductor and patterned, and, the trench is etched.

A mask M2 is deposited on top of the mask M1 and of the semiconductor.

A mask M32 is deposited on top of M1 and M2. In this case, M3 can serve to create region 12 as well as non-implanted regions outside the active region.

The trench body region 5 is implanted.

The masks M1, M2 and M3 are removed and a spacer S1 is fabricated on the sidewalls of the trench. Note that before fabrication S1, a mask is formed to protect implantation of the region 12 (alternatively M3 can be kept).

The mesa is masked in the mesa Schottky contact region. Region 12 is also masked.

The trench source region 6 and the mesa source region 9 are implanted using the same process. The planar channels are created in the trench body regions 5 near the trench bottom between the trench source regions 6 and the CSL 4; the vertical channels are created on the trench sidewalls in the mesa body region 8 between the mesa source region 9 and the body-body separation region 7.

The spacer S1 is removed.

The buffer layer 2 and the drift layer 3 and the current spreading layer 4 and the mesa Schottky contact region may be deposited, for example using the chemical vapor deposition (CVD).

The CSL 4 is optional; if not present, the region, where the CSL 4 is located, inherits the properties of the drift layer 3. The function of the CSL 4 is to increase the doping in the JFET region, which is defined between the trench body regions 5, and below the trench body regions 5, in order to decrease the device resistance.

The mesa Schottky contact region 11 is optional; if not present, the region, where the mesa Schottky contact region 11 is located, inherits the properties of the CSL 4 or of the drift region 3. The function of the mesa Schottky contact region 11 is to define the electrical properties of the Schottky contact.

The Junction Schottky contact region 12 is optional; if not present, the region, where it is located, will be similar to the rest of the planar region (body region 5 and trench source region 6).

The trench body region 5, the trench source region 6, the mesa source region 9 and the mesa body region 8 can be fabricated by ion implantation, while the body-body separation region 7 and the body contact region 10 are fabricated either by ion implantation or by deposition, e.g. CVD.

The body-body separation region 7 is optional; if not present, the region, where the body-body separation region 7 is located, inherits the properties of the CSL 4 or of the drift region 3. The function of the body-body separation region 7 is to prevent from the electrical connection between the trench body region 5 and the mesa body region 8, which can happen due to the trench body ion implantation into the trench sidewalls or due to a prolonged mesa body implantation tail reaching the trench body region 5.

The mask M1 and M3 can be thick hard masks, made of silicon dioxide or silicon nitride or polysilicon or other material, whose etching selectivity against silicon carbide should be high and whose thickness should be large enough to block the ions implanted for the mesa body region 5.

The mask M2 can be a thin hard and conformal mask, made of silicon dioxide or silicon nitride or polysilicon or other material, which prevents from trench sidewall doping during implantation of the mesa body region 5.

The spacer S1 can be made of silicon dioxide or silicon nitride or polysilicon or other material.

The trench body region 5 can be self-aligned to the trench.

The doping concentration of the trench source region 6 and the mesa source region 9 should be lower than the doping concentration of the body contact region 10, in order not to compensate its doping (source region is co-implanted into the body contact region). On the other hand, the doping concentration of the source regions should be high enough, in order to fabricate a low-resistivity ohmic contact on top of those regions. Alternatively, the usage of an extra mask to avoid co-implantation can release from the doping concentration constraint discussed above.

The planar channels can be self-aligned and their length can be decided by a thickness of the spacer S1.

The next part of the fabrication process may include the following steps:

The implanted ions may be activated by post implantation annealing at elevated temperatures.

The semiconductor surface may be preconditioned prior to gate oxide deposition.

A gate oxide may be formed by deposition or oxidation and optionally followed by post deposition/oxidation annealing, for example.

A gate (G) may be formed as a spacer, which may be made of in-situ doped polysilicon.

An interlayer dielectric (ILD) may be formed by deposition of an insulating layer and its patterning, for example or by thermal oxidation of the polysilicon gate.

Ohmic contacts may be created on top of the regions 6, 9 and 10 by metal deposition and annealing.

Opening in the interlayer dielectric to the gate may be created in a gate pad region and the backend processing including front side source metallization(S), backside drain metallization (D), passivation and other steps may be performed. The front side metallization contacts both the ohmic contact region on top of the regions 6, 9, 10 and the mesa Schottky contact region 11.

A typical activation temperature of ions implanted into SiC can be in the range from 1500° C. to 1800° C.

By preconditioning are meant all processes which lead to improvement of trench sidewalls, trench shape (rounding) and semiconductor/oxide interface, for example annealing and/or etching in a hydrogen-ambient.

The gate oxide may be formed using a method providing conformal coverage of sidewalls, for example by TEOS low pressure CVD (LPCVD).

Because the spacer process is used for formation of the gate, the gate is self-aligned on the trench. The width of the spacer gate can be decided by thickness of the deposited layer. The width of the spacer gate should be big enough to overlap the source region.

The interlayer dielectric fabricated using the thermal oxidation is considered to have the following advantages over the deposited layer: a) no photolithography is required and the ILD is self-aligned, b) the mesa is fully exposed to the metal, hence the source contact area is bigger and the source contact resistance is smaller, c) polysilicon is oxidized even in its bottom part, hence the oxide thickness over the source increases and the gate capacitance decreases.

The fabrication of the ILD by the thermal oxidation is possible due to a much smaller oxidation rate of silicon carbide than of polysilicon. The polysilicon can be oxidized at temperatures below 1100° C., at which the SiC surface is hardly oxidized. However, a very thin oxide layer can be still grown on SiC at these temperature, hence short oxide etching is recommended prior to the contact formation.

The contact may be formed for example by the SALICIDE (Self-Aligned Silicide) method. A metal layer, particularly a nickel-based metal, is deposited on the top surface and annealed at moderate temperatures, particularly at 600° C.-700° C. for the nickel-based metal. This step leads to alloying of the metal with SiC (silicidation). The step is followed by wet etching (cleaning), which removes the not alloyed metal from the ILD surface. In the next step, the previously alloyed contacts are exposed to higher temperatures around 1000° C., which assures low-ohmic contact properties.

The full fabrication process may include four self-aligned processes: a) the self-aligned channel (by spacer), b) the self-aligned gate (by spacer), c) the self-aligned ILD (by thermal oxidation), d) the self-aligned contacts (by selective silicidation).

FIG. 5b shows a 3D structure of a fifth embodiment of the semiconductor cell 100.

The device shown in FIG. 5b inherits most properties of the device shown in FIG. 1, but the body contact region is separated into two parts 105 and 108 which make electrical connections to the trench body region 5 and to the mesa body region 8, respectively.

The body contact region 105 has a patterned shape with the trench source region 6. The pattern geometry is not limited to the square form but can have any alternate shape, e.g., zigzag, circles, hexagons, etc.

FIG. 6a shows a 3D structure of a sixth embodiment of the semiconductor cell 100 and a cross section AB of the semiconductor cell 100 through the Junction Schottky section JSBD with illustration of the current conduction path of the JSBD.

The device shown in FIG. 6a inherits most properties of the device shown in FIG. 3. The Junction Schottky contact region 12 is also extending to the trench sidewall 111b of the trench 111 as described above with respect to FIG. 3. That means, the Junction Schottky contact region 12 is not fully surrounded by the trench body region 5. In this configuration, the current density can be improved as illustrated by the current conduction lines shown in FIG. 6a. The device is able to provide a much higher current conduction as the current is not constrained by the trench body region 5.

FIG. 6b shows a 3D structure of a seventh embodiment of the semiconductor cell 100 and a cross section AB of the semiconductor cell 100 through the Junction Schottky section JSBD with illustration of the current conduction path of the JSBD.

The device shown in FIG. 6b corresponds to the device shown in FIG. 1. The Junction Schottky contact region 12 is not extending up to the trench sidewall 111b of the trench 111. That means, the Junction Schottky contact region 12 is fully surrounded by the trench body region 5. In this configuration, the current density is limited by the trench body region 5. The current conduction lines as shown in FIG. 6b are constrained by the trench body region 5. This configuration results in less electric field stress and hence improved life time of the device.

An embodiment of the present disclosure relates to a SiC device for which the doping type of the substrate 1 is of opposite doping type to the doping type of the drift layer 3. The device forms an IGBT structure.

An embodiment of the present disclosure relates to a complementary SiC device for which all semiconductor regions of the previous embodiments are of a reversed doping type.

In the previous sections, a trench-gate planar-gate semiconductor device with monolithically integrated Schottky barrier diode and Junction Schottky barrier diode was presented.

Such a device can be a device with a multiple number of channels, e.g., a device with four channels, for example, where two channels are planar (extend in the trench body regions) and two channels are vertical (extend on the sidewalls or mesa body region), and where each body region is connected to the source by a body contact; the device with integrated Schottky Barrier Diode and Junction Schottky Barrier Diode. Such a device has low resistance due to high channel integration, and at the same time the device reliability, switching speed and dynamic resistance are granted by a presence of a highly doped contact in every body region. In addition, the integrated Schottky and Junction Schottky diodes suppress the operation of the body diode and prevents from bipolar degradation.

In the above device, there is a body contact region connecting all body regions; where the body contact region extends vertically from the top semiconductor surface (mesa body region) at least to the depth of the trench body regions; where the body contact region is produced using deep ion implantation or a combination of trench etching, epitaxial regrowth and surface planarization. The described implementation of the body contact region allows for smaller pitch of the device and for reduction of the number of process steps. Particularly, the number of process steps and the associated process cost are significantly reduced when the body contact region is fabricated using the deep ion implantation.

In the above device, the planar channels can be self-aligned on the trench, e.g., the trench body regions may be implanted using the same mask which is used for etching of trenches (with an optional thin masking layer on top of it) and the trench source regions are subsequently implanted through a spacer mask. This results in decreased pitch of the device due to integration of the self-aligned channel process into the fabrication process flow. Besides, problems of masks misalignments that lead to within unit cell non-uniformities of relevant features (such as channel length, . . . ) can be eliminated by such configuration.

In the above device, forward current (on-state resistance) and Schottky current ratio can be decided by: 1) The area of source contact region (of the mesa) and the area of the Schottky contact region on top of the mesa; and 2) the area of source contact region (in the trench) and the area of the Junction Schottky contact region in the trench.

In the above device, the interlayer dielectric may be formed by oxidation of a polysilicon gate spacer, the oxide thickness over the source regions can be increased compared to the oxide thickness over the channels and the mesa can be fully exposed to the metal. This results in decreased pitch of the device due to self-aligned ILD; decreased mesa source contact resistance due to bigger area exposed to the metal; decreased gate capacitance due to thicker oxide over the source, and increased SBD current due to bigger area exposed to the metal.

In the above device, the polysilicon gate spacer can have reduced thickness prior to the thermal oxidation, which results in exposure of the mesa sidewalls to the metal (mesa source region needs bigger depth in order to achieve the overlay with the polysilicon gate spacer). This results in decrease of mesa source contact resistance and increase of Schottky current due to bigger area exposed to the metal.

The above device can be manufactured by a device fabrication process including four self-aligned processes. This results in decreased pitch of the device due to implementation of the self-aligned processes.

The embodiments described in the present disclosure can be applied to other semiconductor trench devices, for example to MOSFET and IGBT, fabricated using silicon, gallium oxide or other semiconductor material technologies.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the present disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the disclosure beyond those described herein. While the disclosure has been described with reference to one or more particular embodiments, those skilled in the art recognize that many changes may be made thereto without departing from the scope of the disclosure. It is therefore to be understood that within the scope of the appended claims and their equivalents, the disclosure may be practiced otherwise than as specifically described herein.

What is claimed is:

1. A trench-gate planar-gate semiconductor device with monolithically integrated Schottky barrier diode and Junction Schottky barrier diode, the semiconductor device comprising at least one semiconductor cell, the at least one semiconductor cell comprising:
a substrate being arranged at a bottom surface of the at least one semiconductor cell;
a vertical channel section placed above the substrate, the vertical channel section comprising a current spreading layer, a body-body separation region, a mesa body region and a mesa source region;
a planar channel section formed above the substrate and below a trench that is formed on both sides of the vertical channel section, the planar channel section comprising a layer stack of the current spreading layer, a trench body region and a trench source region;
a Schottky section placed above the substrate, the Schottky section comprising the current spreading layer, the body-body separation region and a mesa Schottky contact region;
a Junction Schottky section placed above the substrate, the Junction Schottky section comprising the current spreading layer, the trench body region and a Junction Schottky contact region;
wherein the vertical channel section and the Schottky section are placed in a mesa section of the semiconductor device along a first direction parallel to the bottom surface; and
wherein the planar channel section and the Junction Schottky section are placed below the trench along the first direction parallel to the bottom surface.

2. The semiconductor device of claim 1,
wherein the trench is formed next to the vertical channel section and next to the Schottky section and above the substrate along the first direction, the trench formed on both sides of the vertical channel section and of the Schottky section, the trench comprising a trench bottom and at least one trench side wall, and/or
wherein the trench body region forms a shield below the trench, the shield covering the trench bottom for protection against high electric fields.

3. The semiconductor device of claim 2, comprising:
a body contact region formed in the vertical channel section and the planar channel section along a second direction parallel to the bottom surface, the body contact region electrically connecting the trench body region of the planar channel section with the mesa body region of the vertical channel section,
wherein one or more planar carrier channels are formed in each planar channel section, one or more vertical carrier channels are formed on each trench side wall of the vertical channel section, and one or more Schottky barrier diodes are formed in at least one Schottky section; and
wherein one or more Junction Schottky barrier diodes are formed in each trench bottom.

4. The semiconductor device of claim 3, the at least one semiconductor cell further comprising:
a buffer layer placed on top of the substrate; and
a drift layer placed on top of the buffer layer;
wherein the vertical channel section and the Schottky section and the Junction Schottky section are placed on top of the drift layer.

5. The semiconductor device of claim 4,
wherein the substrate, the buffer layer, the drift layer, the current spreading layer, the trench source region, the body-body separation region, the mesa source region, the mesa Schottky contact region and the Junction Schottky contact region are of a first semiconductor doping type;
wherein the trench body region, the mesa body region and the body contact region are of a second semiconductor doping type,
wherein the Junction Schottky contact region is fully surrounded or at least partly surrounded by the trench body region, and
wherein the Junction Schottky contact region is surrounded by the trench body region on two sides of the Junction Schottky contact region, the two sides extending along the second direction.

6. The semiconductor device of claim 5,
wherein a current density of the semiconductor device in which the Junction Schottky contact region is partly surrounded by the trench body region is higher than a current density of the semiconductor device in which the Junction Schottky contact region is fully surrounded by the trench body region.

7. The semiconductor device of claim 5,
wherein the trench source region is implanted self-aligned through a spacer on the trench body region.

8. The semiconductor device of claim 3,
wherein the current spreading layer is shallower than the trench body region of the planar channel section.

9. The semiconductor device of claim 3,
wherein a first planar carrier channel is formed between the trench source region and the current spreading layer of a first part of each planar channel section and a second planar carrier channel is formed between the trench source region and the current spreading layer of a second part of each planar channel section;
wherein a first vertical carrier channel is formed on each trench side wall between the mesa source region and the current spreading layer of a first part of the vertical channel section and a second vertical carrier channel is formed on each trench side wall between the mesa source region and the current spreading layer of a second part of the vertical channel section;
wherein a Schottky contact is formed on top of the mesa Schottky contact region;
wherein a first Schottky barrier diode is formed by a first part of the Schottky contact and the mesa Schottky contact region of the first part of the vertical channel section and a second Schottky barrier diode is formed by a second part of the Schottky contact and the mesa Schottky contact region of the second part of the vertical channel section; and
wherein a Junction Schottky barrier diode is formed by the Junction Schottky contact region and the trench body region.

10. The semiconductor device of claim 3,
wherein the body contact region is separated in two parts, a first part making electrical connection to the mesa body regions of both parts of the vertical channel section and a second part making electrical contact to the trench body regions of both parts of the planar channel section,
wherein the second part of the body contact region extends to the at least one trench side wall,
wherein the first part and the second part of the body contact region are arranged staggered along the first direction with respect to each other, and
wherein the second part of the body contact region forms a stripe-shaped region extending next to and in parallel to the trench source region; and/or
wherein the second part of the body contact region forms a patterned-shaped region with the trench source region.

11. The semiconductor device of claim 3, the at least one semiconductor cell comprising:
a gate electrode formed in the trench above the planar carrier channels, the gate electrode having an overlay with the trench source region;
a first ohmic contact formed in the trench above the trench source region and the body contact region, the first ohmic contact providing a first part of a source contact;
a first Schottky barrier diode contact formed above the mesa Schottky contact region of a first part of the Schottky section;
a Junction Schottky barrier diode contact formed above the Junction Schottky contact region;
a second Schottky barrier diode contact formed above the mesa Schottky contact region of a second part of the Schottky section; and
a second ohmic contact formed above the mesa source region and the body contact region between the first Schottky barrier diode contact and the second Schottky barrier diode contact, the second ohmic contact providing a second part of the source contact; and
an interlayer dielectric layer electrically separating the gate electrode from the first and second ohmic contacts.

12. The semiconductor device of claim 11,
wherein the interlayer dielectric layer is formed in the trench and overlays the mesa source region on top of the vertical channel section and the mesa Schottky contact region on top of the Schottky section, or
wherein the interlayer dielectric layer is formed in the trench without overlaying the mesa source region on top of the vertical channel section and the mesa Schottky contact region on top of the Schottky section.

13. The semiconductor device of claim 4,
wherein the at least one semiconductor cell is forming a Schottky barrier diode and Junction Schottky barrier diode integrated metal-oxide-semiconductor field-effect transistor (MOSFET) structure; or
wherein a doping type of the substrate is of opposite doping type to the doping type of the drift layer, and
the at least one semiconductor cell is forming a Schottky barrier diode integrated insulated gate bipolar transistor (IGBT) structure.

14. The semiconductor device of claim 3,
wherein the vertical channel section and the Schottky section are placed next to each other along the first direction or along the second direction; or
wherein the vertical channel section and the Schottky section are placed at a distance from each other along the first direction or along the second direction.

15. A method for producing at least one semiconductor cell of a trench-gate planar-gate semiconductor device with monolithically integrated Schottky barrier diode and Junction Schottky barrier diode, the method comprising:
providing a substrate arranged at a bottom surface of the at least one semiconductor cell;
forming a vertical channel section above the substrate, the vertical channel section comprising a current spreading layer, a body-body separation region, a mesa body region and a mesa source region;
forming a trench on both sides of the vertical channel section;
forming a planar channel section above the substrate and below the trench, the planar channel section comprising a layer stack of the current spreading layer, a trench body region and a trench source region;
forming a Schottky section above the substrate, the Schottky section comprising of a current spreading layer, a body-body separation region and a mesa Schottky contact region;
forming a Junction Schottky section above the substrate, the Junction Schottky section comprising the current spreading layer, the trench body region and a Junction Schottky contact region;
wherein the vertical channel section and the Schottky section are placed in a mesa section of the semiconductor device along a first direction parallel to the bottom surface; and
wherein the planar channel section and the Junction Schottky section are placed below the trench along the first direction parallel to the bottom surface.
